(19) United States
(12) Patent Application Publication
(10) Pub. No.: US 2024/0314973 A1
(43) Pub. Date: Sep. 19, 2024

(54) IMPROVEMENTS TO FLOW ENHANCEMENT STRUCTURE FOR IMMERSION COOLED ELECTRONIC SYSTEMS

(71) Applicant: Intel Corporation, Santa Clara, CA (US)

(72) Inventors: Chen ZHANG, Shanghai (CN); Xiang QUE, Suzhou (CN); Yang YAO, Shanghai (CN); Yuehong FAN, Shanghai (CN); Guangying ZHANG, Shanghai (CN); Liguang DU, Shanghai (CN); Shaorong ZHOU, Shanghai (CN); Chuanlou WANG, Shanghai (CN); Yingqiong BU, Shanghai (CN); Yue YANG, Shanghai (CN)

(21) Appl. No.: 18/671,881

(22) Filed: May 22, 2024

(30) Foreign Application Priority Data
Apr. 19, 2024 (WO) PCT/CN2024/088760

(51) Int. Cl. H05K 7/20; H05K 1/02

(52) U.S. Cl. CPC H05K 7/20236; H05K 1/0203; H05K 7/20272; H05K 7/20281; H05K 7/20409; H05K 7/20763; H05K 7/20263

(57) ABSTRACT

An apparatus is described that includes an immersion bath chamber and a cover that is to seal the immersion bath chamber. An apparatus is described that includes an immersion bath chamber and an installable/removable transfer member. The installable/removable transfer member has fluidic connectors designed to couple to respective warmed fluid flow output ports of pluggable units to be cooled in the immersion bath chamber and having respective backplane interface designs. An apparatus is described that includes an immersion bath chamber and an overflow chamber. The overflow chamber is to receive an overflow of liquid coolant from the immersion bath chamber, wherein a first exit flow channel from the overflow chamber is coupled to a second exit fluid flow channel from the immersion bath chamber through a valve, wherein, an opening of the valve is controllable to vary a gravitational fluid flow within the immersion bath chamber.

### CLAIM OF PRIORITY

The present application claims the benefit of priority to Patent Cooperation Treaty (PCT) Application No. PCT/CN2024/088760, filed Apr. 19, 2024, the entire content of which is incorporated herein by reference.

### BACKGROUND OF THE INVENTION

With the increased performance and power consumption of high performance computing environments (such as data centers), system designers are continually seeking ways to improve the cooling technology of the underlying electronic components that generate heat.

### BRIEF DESCRIPTION OF THE DRAWINGS

FIG. 1 depicts an immersion cooling system in accordance with one or more embodiments of the invention;

FIGS. 2a and 2b depict circuit boards immersed in an immersion chamber in accordance with one or more embodiments of the invention;

FIG. 3 shows a printed circuit board with a flow enhancement structure in the vicinity of the fins of a heat sink in accordance with one or more embodiments of the invention;

FIGS. 4a, 4b, 4c and 4d depict an electronic unit assembly with a flow enhancement structure in the vicinity of the fins of a heat sink in accordance with one or more embodiments of the invention;

FIGS. 5a, 5b, 5c and 5d pertain to a flow enhancement structure that also acts as a CDU return flow intake in accordance with one or more embodiments of the invention;

FIGS. 6a and 6b pertain to an immersion chamber design to have a pressurized fluid flow head in accordance with one or more embodiments of the invention;

FIGS. 7a, 7b, 7c, 8, 9, 10, 11a and 11b pertain to an immersion chamber design having a transfer plate in accordance with one or more embodiments of the invention;

FIGS. 12a, 12b, 13a, 13b, 13c, 14, 15, 16a, 16b, 16c and 16d pertain to an immersion chamber design having an overflow chamber in accordance with one or more embodiments of the invention;

FIG. 17 shows a data center environment in accordance with one or more embodiments of the invention.

### DETAILED DESCRIPTION

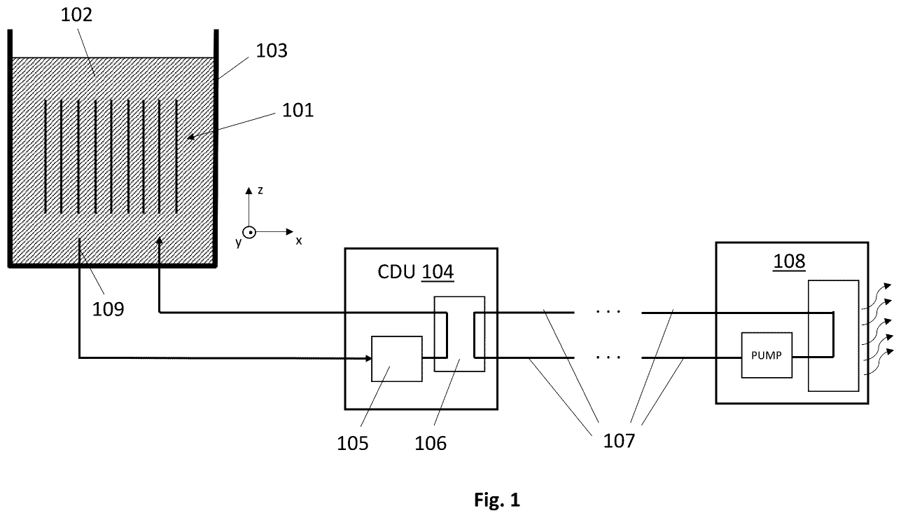

FIG. 1 depicts an immersion cooling system. As observed in FIG. 1, a plurality of electronic circuit boards 101 are immersed in a dielectric liquid 102 that electrically isolates the exposed electrical nodes of the electronic circuit boards 101 and their respective electronic components (FIG. 1 depicts a side view of the circuit boards 101 oriented vertically within the liquid 102). The electronic components, when in operation, generate heat which is transferred to the liquid 102. The liquid 102 has a higher specific heat than air which enables heat to be removed from the electrical components more effectively than would otherwise be achievable in an air-cooled environment.

An immersion bath chamber 103 is fluidically coupled to a coolant distribution unit (CDU) 104 that includes a pump 105 and heat exchanger 106. During continued operation of the electronic components, the liquid's temperature will rise as a consequence of the heat it receives from the operating electronics. The pump 105 draws the warmed liquid 102 from the immersion bath chamber 103 to the heat exchanger 106. The heat exchanger 106 transfers heat from the warmed fluid to a secondary liquid within a secondary cooling loop 107 that is fluidically coupled to a cooling tower and/or chilling unit 108. The removal of the heat from the liquid 102 by the heat exchanger 106 reduces the temperature of the liquid which is then returned to the chamber 103 as cooled liquid.

In a high computing environment, such as a data center, the respective CDUs of multiple immersion bath chambers are coupled to the secondary loop 107, and, the cooling tower and/or chilling unit 108 removes the heat generated by the electronics within the multiple immersion bath chambers from the data center.

With the increasing performance and corresponding heat dissipation of the electronic components within the immersion bath 102, engineers and technicians are continually seeking ways to improve the efficiency of the thermal transfer from the circuit boards' respective electronic components to the immersion bath liquid 102.

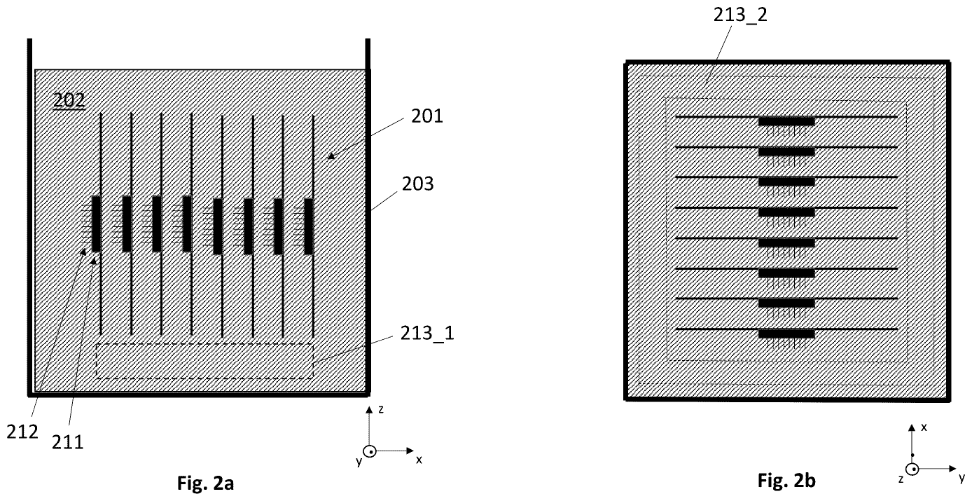

FIGS. 2a and 2b depict a plurality of circuit boards 201 immersed within a liquid 202 within an immersion bath chamber 203 (FIG. 2a shows a side view whereas FIG. 2b shows a top-down view). Notably, the circuit boards 201 are vertically oriented such that the respective faces of the high-performance semiconductor chip packages, and the fins 212 of the heat sinks 211 that are coupled to them, are normal to the horizontal x axis (for case of illustration, each of the circuit boards 201 include only one high performance chip package and corresponding heat sink).

Ideally, the immersion bath liquid 202 exhibits a high rate of fluid flow through the heat sink fins 212 so that the large amounts of heat generated by the one or more semiconductor chips that are operating within the underlying chip package can be efficiently transferred to the immersion bath 202. Unfortunately, referring to FIG. 2b, the particular arrangement of circuit boards imposes impediments to the creation of such currents.

Firstly, horizontal flow of cooled fluid along the x axis is essentially blocked by the circuit boards 201. Secondly, with the chamber walls, the circuit boards 201 and the circuit boards' respective electronics and packaging introducing large surface areas that the fluid 202 is to flow over, the fluid 202 experiences viscosity forces that resist its flow throughout the chamber 203, generally (the viscosity forces are proportional to the surface areas of the chamber walls, the circuit boards 201 and the circuit boards' respective electronics and packaging).

Thirdly, to the extent attempts have been made to induce high velocity currents that run horizontally along the y axis or along the vertical z axis, such attempts have placed various structures and/or components (e.g., baffles, jets) in peripheral regions 213_1, 213_2 outside the circuit boards 201. Unfortunately, with the currents being directed toward the heat sinks 211 from the periphery 213_1, 213_2, the heat sinks 211 can impose flow impedances that cause the currents to flow around the heat sinks 211 rather than through their fins 212.

Finally, the immersion bath liquid 202 has appreciable density and corresponding mass that causes the fluid 202 to experience downward (−z) gravitational forces that act against upward (buoyant) fluid flow in the +z direction. The lack of upward fluid flow, combined with the aforementioned viscous forces, causes flow stagnations and re-circulations within the chamber 203, which, in turn, result in insufficient fluid flow (upward or otherwise) through the heat sink fins 212.

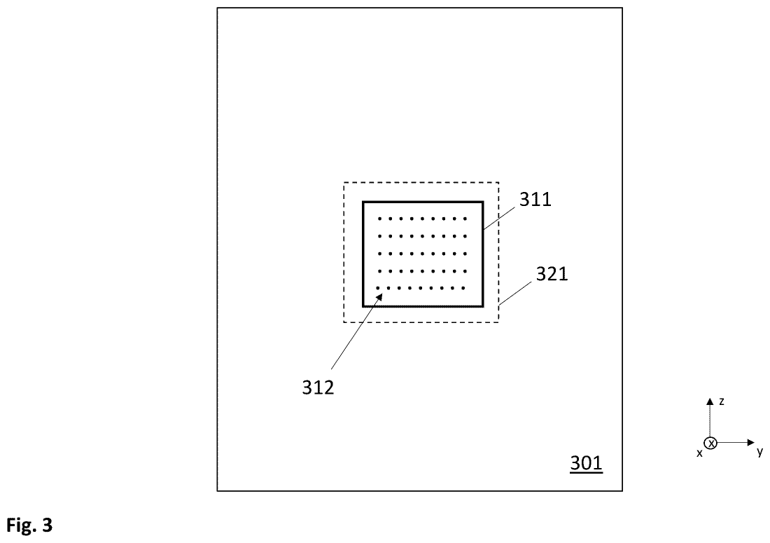

A solution, referring to FIG. 3, is to place a flow enhancement structure 321 in the vicinity of a heat sink 311 that creates a high velocity fluid flow through the space between heat sink's fins 312 (which can also be stated as “through the fins”). With a flow enhancement structure 321 positioned in the vicinity of the heat sink 311 and/or the heat sink's fins 312, the higher velocity fluidic currents that are created by the enhancement structure 321 will flow through the heat sink's fins 312 thereby improving the thermal transfer efficiency from the fins 312 to the liquid.

Notably, as compared to previous solutions that only direct or increase fluid flow generally over a multitude of components, e.g., from the periphery 213 of an electronic circuit board (as described above with respect to FIGS. 2a and 2b), by contrast, the flow enhancement structure 321 is designed to direct and/or increase fluid flow through the fins 312 of a heat sink 311 specifically.

For ease of illustration, again, only a single heat sink 311 is depicted on the circuit board 301 of FIG. 3. It is pertinent to point out that other circuit boards can have multiple high-performance chip packages and corresponding heat sinks per board. In such instances, a respective flow enhancement structure 321 can exist in the proximity of each heat sink (multiple flow enhancement structures per board), an enlarged flow enhancement structure 321 can be designed to enhance fluid flow through the respective fins of multiple heat sinks, some combination of these, etc. Thus, although the following description largely continues to present a single heat sink per circuit board, the reader should bear in mind that the teachings provided below can be readily extended to other types of circuit boards.

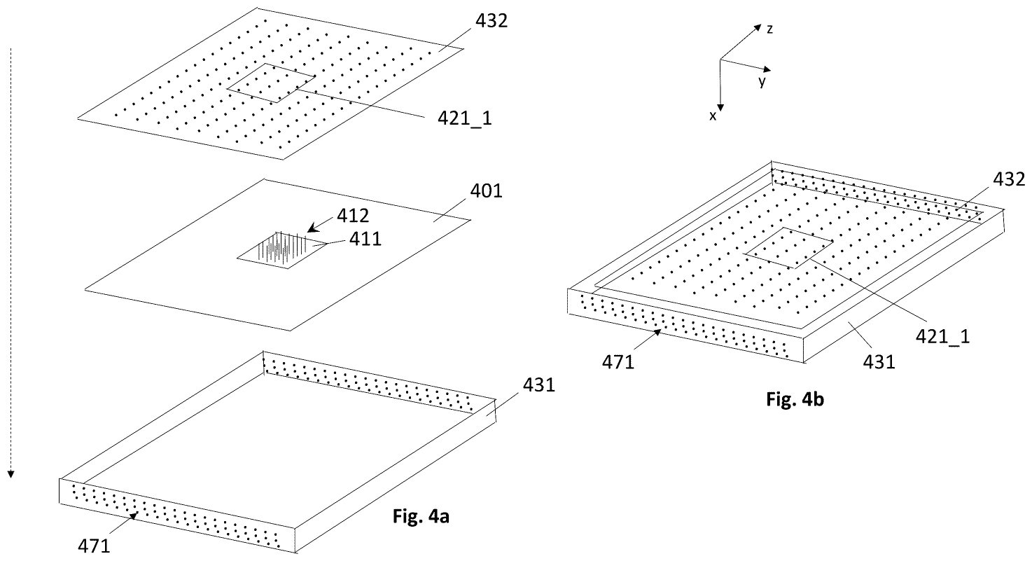

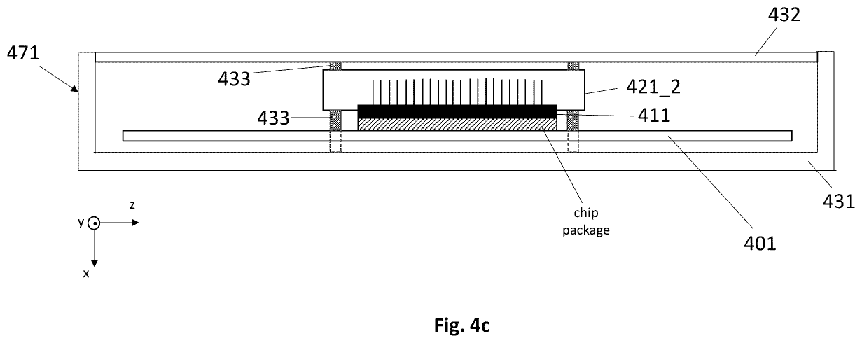

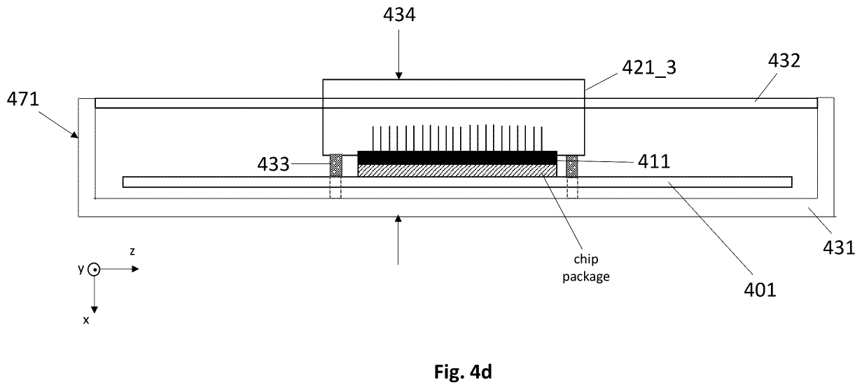

FIGS. 4a through 4d pertain to more detailed embodiments in which a printed circuit board is integrated into a larger assembly 400 before being submersed into the immersion bath. As described in more detail below, the assembly 400 can be a pluggable electronic unit that plugs into an electrical/mechanical interface (or purely mechanical interface) within the immersion bath.

Examples of such pluggable units include a blade server, a CPU unit, an accelerator unit, a memory unit, storage unit, etc. Here, the function of the pluggable electronic unit largely corresponds to the functions that the assembly's printed circuit board 401 are designed to perform or support (e.g., a computing system in the case of a blade server, one or more multi-core processor chips in the case of a CPU unit, one or more accelerators (e.g., one or more neural network chips, artificial intelligence machine learning chips, artificial intelligence inference engine chips, graphics processing unit (GPU) chips, etc.) in the case of an accelerator unit, multiple memory chips (e.g., multiple dual in-line memory modules (DIMMs)) in the case of a memory unit, multiple storage devices (e.g., multiple solid state drives (SSDs)) in the case of a storage unit, etc.).

As observed in FIGS. 4a and 4b the assembly 400 includes a frame 431, the printed circuit board 401 and a cover 432 (FIG. 4a shows an exploded view whereas FIG. 4b shows the completed assembly). The printed circuit board 401 is mounted to the frame 431 (e.g., with screws, bolts or other types of fasteners) and the cover 432 is mounted to the printed circuit board 401 and/or the frame 431.

The frame 431 mechanically supports the printed board 401 whereas the cover 432 mechanically protects the printed circuit board 401 and its electronic components from mechanical shocks/blows that can be imparted to the assembly 400, e.g., during insertion/removal of the assembly to/from the immersion liquid. Notably, the frame 431 and cover 432 have various perforations or other openings that allow fluid to enter the space where the printed circuit board 401 resides so that the electronic components can be cooled by fluidic flow through the assembly 400.

As observed in the particular embodiment of FIGS. 4a and 4b, a flow enhancement structure 421_1 is integrated into the cover 432 of the assembly 400 in the proximity of the heat sink 411 and/or the heat sink's fins 412.

In still other embodiments, as observed in the side view of FIG. 4c, the flow enhancement structure 421_2 is composed of one or more structures and/or devices that are mechanically secured 433 to the cover 432, printed circuit board 401 and/or frame 431. For example, mechanical structures and/or active electrical components that enhance flow through the heat sink fins 412 are mounted to posts that emanate from the printed circuit board 401 and/or frame 431.

In still other embodiments, the flow enhancement structure is formed from a combination of elements that are formed in the cover 432 and individual elements that are mounted to any/all of the cover 432, printed circuit board 401 and frame 431.

FIG. 4d provides another side view that demonstrates that at least some flow enhancement structures 421_3 can extend beyond the cover 432 in the −x direction. Here, however, in various embodiments, the “height” 234 of the overall assembly along the x axis remains within, e.g., an industry standard dimension that specifies a pluggable unit's maximum dimension along the x axis. For example, in the case of pluggable electronic units that are designed to conform to an industry standard format that specifies maximum dimension along the x axis in units of U, the extension of the flow enhancement structure 421_3 beyond the cover 432 does not cause the assembly's widest dimension 234 along the x axis to exceed the applicable standard's maximum U specified dimension along the x axis.

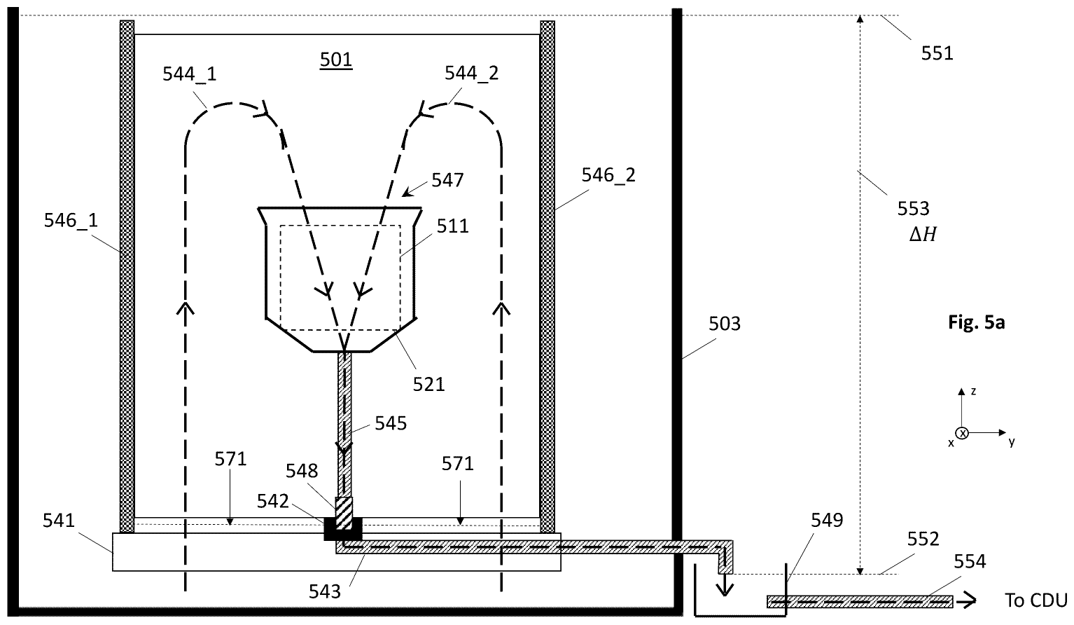

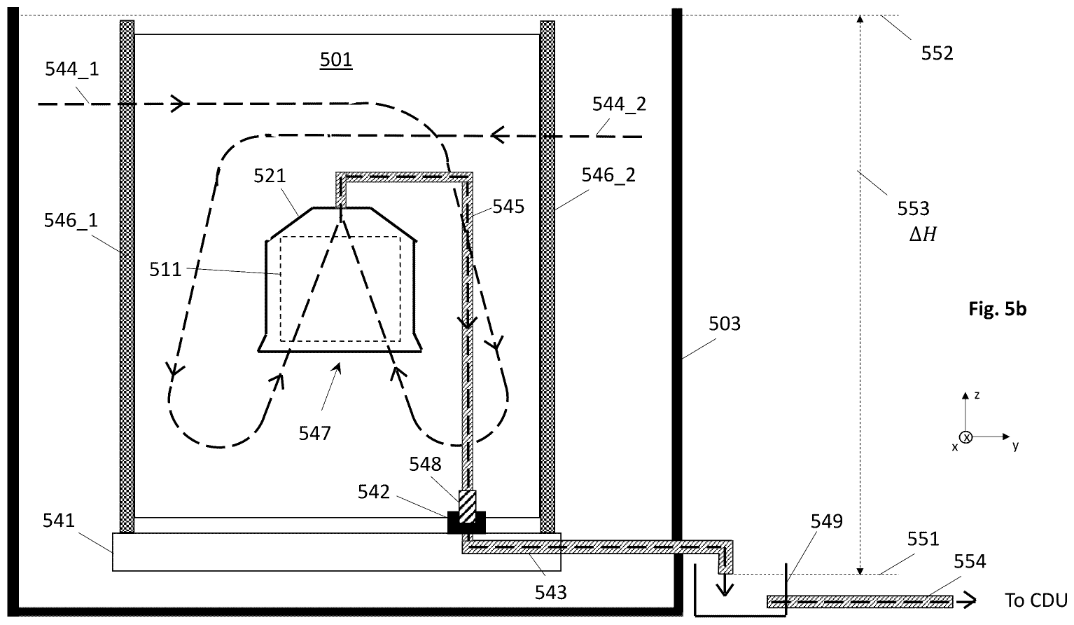

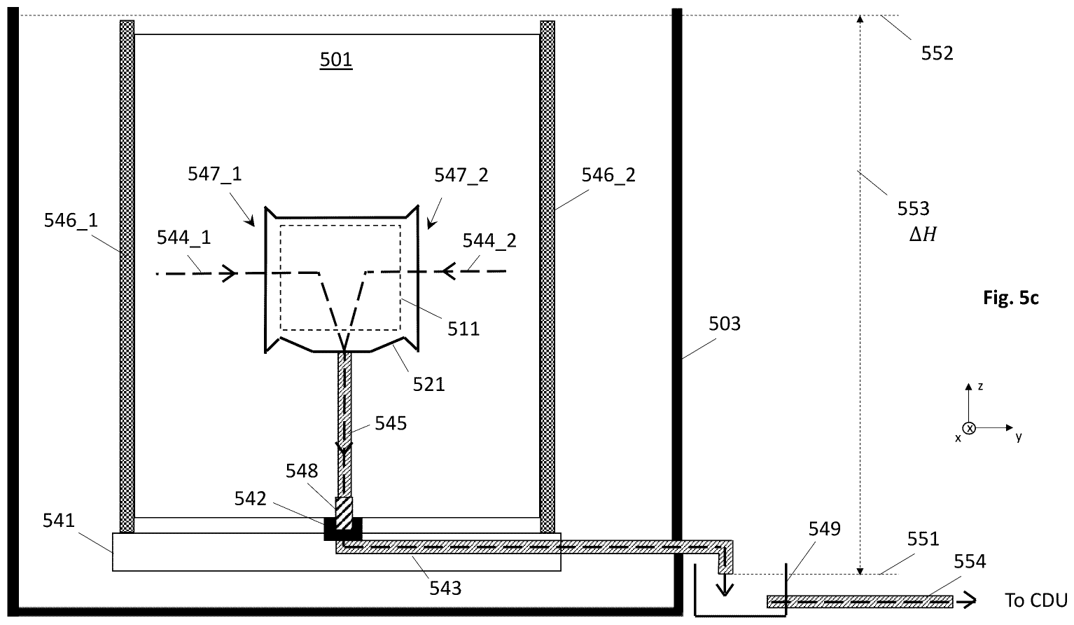

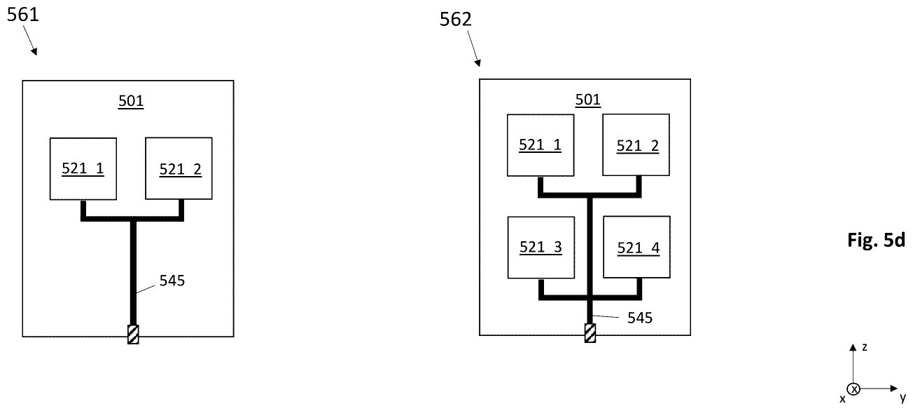

FIGS. 5a through 5d are directed to various embodiments of a flow enhancement structure 521 that not only increases fluid flow rate through the fins of the underlying heat sink 511 but also acts as an intake duct for the liquid coolant return to the CDU. Here, referring to FIG. 5a, the flow enhancement structure 521 is coupled to a fluidic channel 545 (e.g., a hose, a pipe, etc.) that is coupled on an opposite end to a CDU fluidic return channel 543. Referring to both FIG. 5a and FIG. 1, the CDU fluidic return channel 543 corresponds to CDU return channel 109 of FIG. 1, or, a fluidic channel that feeds into the CDU return channel 109 of FIG. 1.

In various embodiments, the immersion bath includes a framework having multiple slots that respective pluggable electronic units can plug into. In the particular embodiment of FIG. 5a, each slot includes a pair of guide rails 546_1, 546_2 that run along the respective sides of the pluggable unit and a backplane 541 that the pluggable unit physically plugs into. The backplane 541 includes a first fluidic connector 542 (e.g., a receptacle) that is aligned with a corresponding second fluidic connector 548 (e.g., a nozzle) that is attached to the end of the fluidic channel 545.

During installation of a pluggable unit, the pluggable unit is entered into the slot from the top of the immersion bath and pressed downward in the −z direction along the guide rails 546_1, 546_2 until it is plugged into the backplane 541. As part of the installation into the slot, the first fluidic connector 542 is connected to the second fluidic connector 548 thereby fluidically coupling the channel 545 that emanates from the flow enhancement structure to CDU return line 543.

During operation of the particular embodiment of FIG. 5a, cooled fluid 544_1, 544_2 from the CDU is injected upward in the +z direction from beneath the pluggable unit. The upward injection induces currents of cooled immersion bath fluid that flow upward over the pluggable unit's electronics but flow around the flow enhancement structure 521 which covers the heat sink 511 (in the particular embodiment of FIG. 5a, the bottom end of the flow enhancement structure 521 is shaped to cause the upward flow to curve around the structure 521).

The fluid continues to flow 544_1, 544_2 upward above the duct 547. Due to suction from the CDU pump and/or gravity, the immersion coolant flows 544_1, 544_2 are drawn into the intake duct opening 547 of the flow enhancement structure 521. The fluid 544_1, 544_2 then flows through the flow enhancement structure 521 (ideally, with a high fluidic velocity).

Here, the flow enhancement structure 521 is designed as a kind of housing that encompasses the fins of the heat sink 511 of a high performance chip package that resides directly beneath the flow enhancement structure 521. With the immersion coolant 544_1, 544_2 flowing at a high velocity through the flow enhancement structure 521, and with the flow enhancement structure 521 confining the currents 544_1, 544_1 to flow through the space between the fins of the heat sink, heat is transferred from the heat sink fins to the immersion bath flows 544_1, 544_1 with high efficiency (low thermal resistance).

Notably, because the high performance semiconductor chip(s) within the chip package beneath the heat sink 511 generate most of the pluggable unit's heat, as the currents 544_1, 544_2 flow around the flow enhancement structure 521 immediately after injection into the bath, they do not capture significant heat because they flow through/across electronics that generate significantly less heat than the chip(s) in the high performance chip package beneath the heat sink 511. As such, the temperature of the fluid as it enters the intake duct 547 should be relatively cool (the temperature is only slightly warmed than the temperature of the fluid that enters the immersion bath from the CDU).

As discussed above, higher thermal transfer efficiencies from the heat sink fins to the fluid within the flow enhancement structure 521 is achieved with increasing fluid flow velocity through the structure 521. In order to increase the flow rate through the enhancement structure 521, the draw/suction from the CDU pump can be increased.

In other approaches, however, e.g., to avoid excessively powerful/expensive CDU pump equipment, the flow rate through the flow enhancement structure 521 is increased by establishing a sufficiently large height difference 553 between the upper surface 552 of the coolant within the immersion bath chamber 503 (upper liquid free surface 552) and an opening 551 in the CDU return line 543 (lower liquid free surface 551).

Specifically, as observed in FIG. 5a, the immersion coolant that flows from the immersion bath chamber 503 toward the CDU through return line 543 flows through an opening 551 in the return line 543 and into a plenum 549. The plenum 549 collects the fluid and the CDU pump draws the coolant from the plenum 549 through return line 554 to be cooled.

Importantly, the opening 551 in the return line 543 and an opening in the plenum 549 physically connects the lower liquid free surface 551 to the same ambient as the upper liquid free surface 552. With this arrangement, gravity will cause the rate of fluid flow through the enhancement structure 521 to increase as the height difference 553 between the upper and lower liquid free surfaces 552, 551 increases. As such, for example, extremely high flow rates through the flow enhancement structure 521 can be achieved (e.g., without expensive/powerful CDU pump equipment) by setting the opening 551 in the CDU return line 543 and the plenum 549 sufficiently below the immersion bath chamber 503.

It is pertinent to point out that the specific flow patterns 544_1, 544_2 and intake duct arrangement 547 of FIG. 5a are just one example and that many other flow patterns and intake duct arrangements are possible (e.g., the locations of the inlet/outlet of the liquid flowing to/from the immersion bath chamber and the flow enhancement structure 521 can be various). For example, FIG. 5b shows another approach in which the intake duct 547 faces the bottom of the immersion bath. Here, liquid coolant 544_1, 544_2 is injected along the y axis into the sides of the pluggable unit and flow into the bottom intake duct opening 547 to return back to the CDU. FIG. 5c shows yet another possible arrangement in which there are multiple intake duct openings 547_1, 547_2 on the sides of the flow enhancement structure.

FIG. 5d also shows that the return line from multiple flow enhancement structures on a single pluggable unit can flow feed into one another, e.g., a single fluidic interface at the backplane. Specifically, drawing 561 shows an electronic circuit board 501 having two high-performance chip packages and corresponding flow enhancement structures 521_1, 521, whereas, drawing 562 shows an electronic circuit board having four high-performance chip packages and corresponding flow enhancement structures 521_1, 521_2, 521_3, 521_4. In both drawings 561, 562, the CDU return flow from the set of flow enhancement structures flow into a common CDU return channel 545.

Note that electro-mechanical interfaces can also exist at the backplane 541, and/or, can be coupled to the pluggable unit through the upper surface of the immersion bath 551. In various embodiments (as suggested by FIGS. 5s, 5b and 5c), the backplane 541 is simply a fixture at/near the bottom of an immersion bath chamber 503 that aligns the pluggable unit's fluidic connector 542 with the corresponding connector 542 that is attached to the CDU return line 543. As such, backplane feature 541 need not extend end-to-end across the width of the electronic unit along the y axis and can instead be, e.g., a simple mechanical fixture that merely holds and aligns connector 542 (and perhaps provides mechanical support for CDU return line 543).

Consistent with the discussion of FIGS. 4a through 4d, any of the flow enhancement structures 521 and/or fluidic channels 545 of FIGS. 5a through 5d discussed above can be: 1) a feature that is designed into the cover 432 of the assembly; 2) a standalone feature that is mounted to the circuit board 401 and/or the frame 431 of the assembly; or, 3) some combination of 1) and 2) above.

In various embodiments, one or more traditional CDU return lines are also coupled to the chamber 503 so that less than all of the CDU return flows through the chamber's flow enhancement structure(s).

Although the embodiments of FIGS. 5a through 5d have been directed to an approach in which the flow enhancement structure 521 acts as an intake for a CDU return flow, in other embodiments, the flow enhancement structure 521 is coupled to a cooled fluid line from a CDU (with a fluidic channel similar to channel 545) and runs cooled fluid from the CDU through the structure 521 and space between the heat sink fins before the fluid is emitted from the flow enhancement structure to cool components in the immersion bath other than the component that the heat sink fins are coupled to.

### Immersion Bath Chamber Improvements

Certain additional challenges and/or optimization opportunities can arise when attempting to implement an immersion bath chamber having, e.g., a pluggable unit that includes a flow enhancement structure for a high performance semiconductor chip of the pluggable unit as described above, and/or, an immersion bath chamber that is designed to induce gravitational fluid flow as described above. Certain challenges and embodiments of their respective solutions are described immediately below.

### 1. Increased Bath Pressure to Achieve Increased Fluidic Pressure Head

The heat removal capacity of a heat sink within a flow enhancement structure as described at length above improves within increasing fluid flow velocity through the flow enhancement structure.

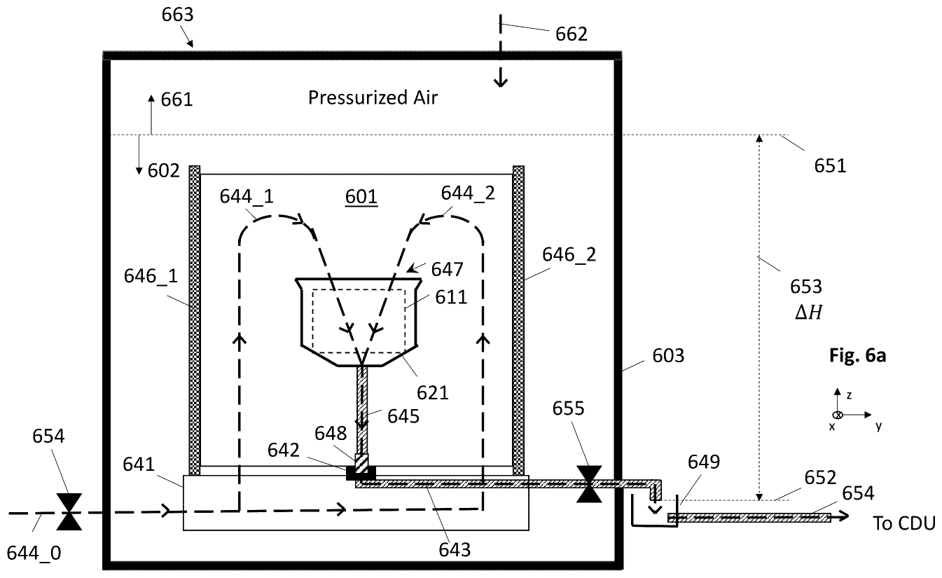

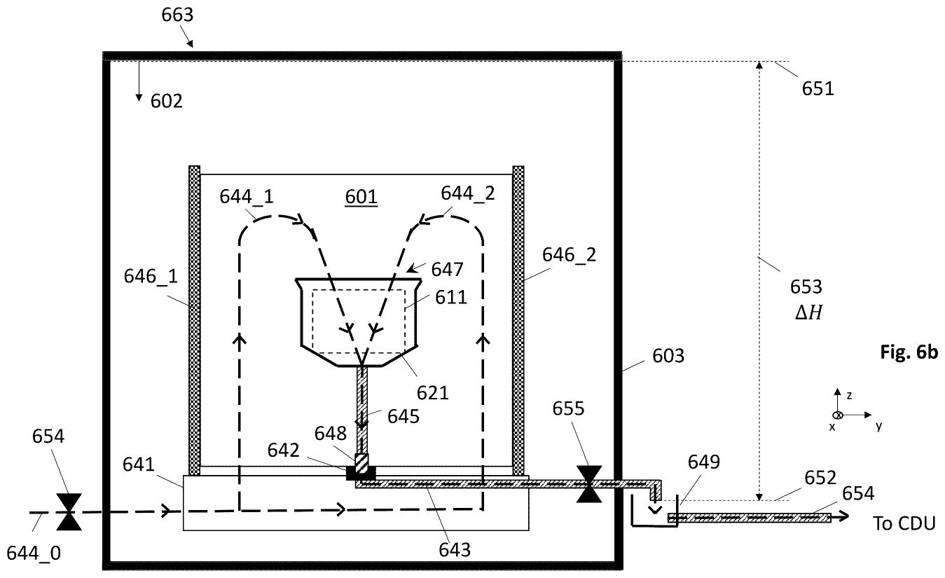

FIGS. 6a and 6b pertain to an approach that increases the pressure of the liquid coolant within the chamber 603 to increase the flow of coolant through the flow enhancement structure 621 and the CDU return channel 643. By increasing the pressure of the liquid in the chamber 603, the “pressure head” of the fluid through the flow enhancement structure 621 and CDU return channel 643 is increased beyond the gravity induced pressure head that is achieved with height difference 653. With increased pressure head, improved heat removal capacity can be achieved as compared to, e.g., the system as described above with respect to FIGS. 5a, 5b and 5c.

For instance, a higher fluid flow rate will be observed through the heat sink, and/or, the heat sink can be replaced with a heat sink having increased fin density (and therefore greater heat removal capacity). In the case of the former, the higher pressure head results in increased fluid velocity through a same fluidic impedance. In the case of the later, the higher pressure head results in an ability to drive an increased fluidic impedance. For ease of discussion, the remainder of the discussion assumes the heat sink remains unchanged such that higher fluid flow through the heat sink is realized.

As observed in the particular example of FIG. 6a the height of the liquid coolant reaches a level 651 within the chamber 603. Liquid coolant 602 therefore resides beneath this level 651 whereas air 661 resides above this level 651 within the chamber 603. The chamber 603 also includes a sealed lid 663 which confines the air 661 within the chamber 603. The confined air 661 within the chamber is pressurized, e.g., by pumping air 662 (or other gas) into the space within the chamber 603 above the coolant 602.

The pressurized air 661 above the liquid coolant 602 within the chamber 603 exerts pressure against the liquid coolant 602, which, in turn, drives additional fluid flow through the flow enhancement structure 621 and CDU return channel 643. The increased fluid flow translates into increased heat removal capacity of the immersed heat sink 611. Again, the increased fluid flow and heat removal capacity is in addition to whatever fluid flow and heat removal capacity is achieved through gravity as a consequence of height 653.

Notably, the pressurization/pumping 662 of the air 661 need not be continuous during operation of the electronics 601 within the chamber 603. For example, during initial installation of the electronic circuit board(s) 601 within the immersion bath 602 and chamber 603 the lid 663 can be secured on the chamber 603 to form a sealed system. Air can then be injected/pumped 662 into the air space 661 within the chamber 603, e.g., by way of a valve that is integrated on the lid 663.

The pumping of the air into the space 661 increases the pressure of the air space 661 which, as described above, will provide additional fluid flow “pressure head” through the flow enhancement structure 621. The valve that is integrated into the lid 663 is then closed and the injection/pumping of air into the space 661 stops. With the chamber 603 being sealed, the pressurized air condition within space 661 will remain approximately constant over extended periods of time.

Here, the increased fluid flow out of the chamber 603 (through the flow enhancement structure 621 and CDU return channel 643) that results from the pressurized space 661, and that left alone will act to reduce the pressure within the space 661, can be compensated for by increasing the rate at which fluid 644_1, 644_2 is pumped into the chamber 603.

Said another way, any lowering of level 651 that can/could result from the increased pressure within space 661 can be compensated for (or otherwise mitigated) by increasing the rate of fluid flow rate 644_1, 644_2 into the chamber 603. In this state, the chamber is essentially a closed system that is able to maintain the enhanced fluid flow that results from the pressurized air space 661 for an extended period of time in which the electronics 601 continually operate.

FIG. 6b shows another embodiment in which there is little/no airspace beneath the chamber lid 663 (e.g., the chamber is completely filled with coolant liquid). In this approach, increased pressurization of the coolant liquid 602 is achieved by increasing the rate of fluid flow 644_1, 644_2 into the chamber. That is, the increased liquid coolant pressure within the chamber 603 is achieved by, e.g., increasing the pumping activity of the pump (e.g., the CDU pump) that pumps fluid 644_1, 644_2 into the chamber 603. Increased fluid flow through the flow enhancement structure 621 and CDU return channel 643, and corresponding increase in heat removal capacity, results from the increased liquid coolant pressure head as described at length above.

Notably, the increased pressure from input liquid flows 644_1, 644_1 can be effected with an input valve 664 that is located at a fluid input 644_0 to the chamber 403. By increasing the opening of the input valve 664, increased fluid flow rate will be observed for input flows 644_1, 644_2. The input valve 664 can be precisely opened to a wider opening to achieve a desired increase in fluid flow rate through the flow enhancement structure 621 and CDU return channel 643 for embodiments that rely on increased air pressure (FIG. 6a) and/or increased input fluid flow 644_0 (FIG. 6b) to effect increased chamber fluid pressure.

Alternatively or in combination, an output valve 665 can be placed along the chamber's fluid return line to achieve a similar effect. Namely, the output valve 665 can be precisely narrowed to a narrower opening to increase the fluidic impedance out of the chamber which, in turn, increases the pressure of the liquid coolant 602 within the chamber 603 (which in turn increases the fluid flow through the flow enhancement structure 621).

Note that combined embodiments can exist where the pressure of the liquid coolant 602 is increased to effect higher flow rate through the flow enhancement structure 621 with both increased air pressure (FIG. 6a) and liquid flow rate into and/or out of the chamber (FIG. 6b).

Although embodiments above have stressed that a “lid” is the component that seals the chamber, in other embodiments, another type of chamber cover (e.g., a portion of a chamber sidewall) can be used to seal the chamber to enhance the pressure head of the coolant.

### 2. Transfer Plate to Improve Submersed Pluggable Unit Configuration Ability

Another challenge is ensuring that a variety of different pluggable electronic units can easily “plug into” the backplane of any particular immersion chamber. Here, recall from the discussion of FIGS. 4a through 4d that a circuit board having one or more high performance semiconductor chips with corresponding flow enhancement structure(s) can be integrated into a larger assembly such as a pluggable electronic unit (e.g., a blade server, a CPU unit, an accelerator unit, a memory unit, storage unit, etc.).

Here, briefly referring back to FIGS. 4a, 4b and 5a, different pluggable electronic units can have different chassis backplane interface designs including, different numbers of fluid flow exit ports on the chassis backplane interface 471, 571, different fluid flow exit port connector types on the chassis backplane interface 471,571, and/or, different location(s) for the fluid flow exit port(s) on the chassis backplane interface 471, 571. Here, the chassis backplane interface 471, 571 is the face of the pluggable unit chassis that fluidically couples to the CDU return line 543. A fluid flow exit port is, e.g., a fluidic connector 548 of the chassis that is fluidically coupled downstream from the output port of at least one flow enhancement structure of the chassis.

With respect to different pluggable electronic units having different backplane interface 471, 571 designs, as just one example, a first blade server may have two fluid flow exit ports of a first connector type that are spaced a first distance apart on the first server's chassis backplane interface, whereas, a second type of blade server may have four fluid flow exit ports of a second connector type that are spaced a second (different than the first) distance apart on the second server's chassis.

Notably, the different chassis backplane interface designs can cause complications when an operator desires to install a set of pluggable units having different backplane interface designs into any single immersion chamber.

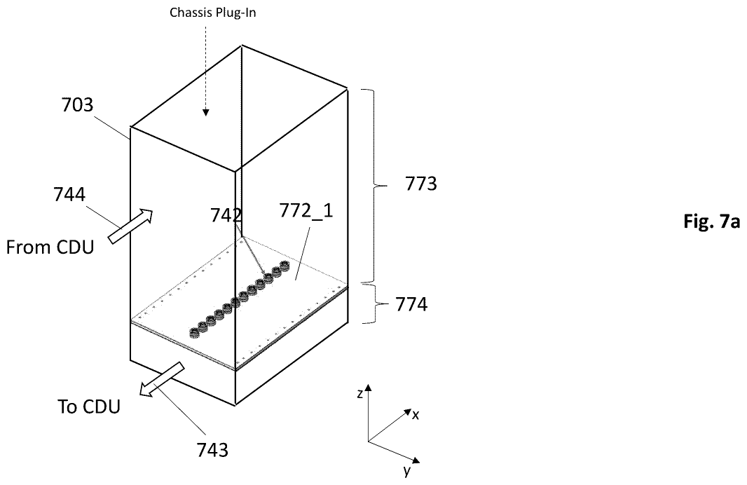

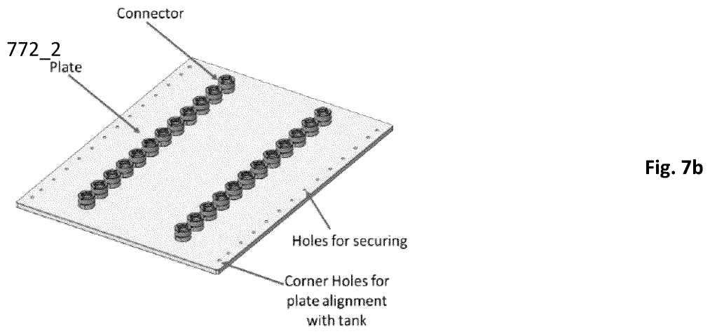

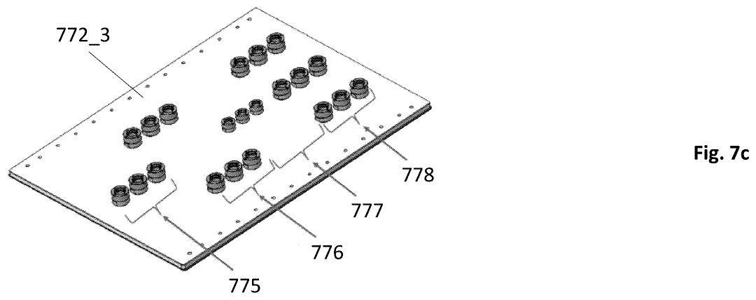

A solution, as observed in FIG. 7a, is to implement the chamber backplane as an installable/removable transfer plate 772_1 that serves as a mechanical interface between the immersion chamber 703 and the particular backplane interface design of an electronic pluggable unit that is to be installed into the immersion chamber 703.

Here, the immersion chamber 703 has mechanical mounting fixtures (e.g., alignment posts, alignment holes, threaded holes, threaded studs, etc.) that receive corresponding mechanical mounting fixtures that are integrated on the “downward” face of the transfer plate 772_1 (which faces the bottom of the immersion chamber 703 as is not observable in FIG. 7a). The transfer plate 772_1 is mounted to the immersion chamber 703 by securing the immersion chamber's and transfer plate's respective mounting fixtures to one another (for case of illustration the mechanical mounting fixtures are not observed in FIG. 7a).

Importantly, the “upward” face of the transfer plate 772_1 (which is observed in FIG. 7a) is designed with one or more fluidic connectors, each being of a specific type and having a specific location on the transfer plate 772_1, to couple with the corresponding fluid exit ports of the particular electronic pluggable units that are to be installed in the chamber 703.

In the particular example of FIG. 7a, the observed transfer plate 772_1 supports, e.g., twelve pluggable units each having a single, centralized fluid exit port (such as the exemplary electronic pluggable units of FIGS. 5a through 5d). That is, the observed transfer plate 772_1 of FIG. 7a includes twelve fluid flow connectors that are aligned along the x axis at a central y axis location (for ease of illustration only one 542 of the connectors is assigned a reference number).

Thus, when a pluggable unit having a particular backplane interface design is to be plugged into the immersion bath chamber 703, an operator first mounts the transfer plate for the pluggable unit's particular chassis backplane interface design to the immersion chamber 703. The selected transfer plate 772_1, as described just above, has integrated fluid flow connectors whose type and location on the transfer plate are designed to align with and couple to the pluggable unit's fluid flow exit flow port(s).

The operator of the immersion chamber can therefore possess a collection of different transfer plates to support pluggability of a corresponding collection of different pluggable units having different respective backplane interface designs. For example, an operator may possess a first transfer plate 772_1, as observed in FIG. 7a, to support twelve pluggable units each having a single fluidic output port. The same operator may also possess a second transfer plate 772_2, as observed in FIG. 7b, to support twelve pluggable units each having dual fluidic output ports.

In this case, if the operator chooses to replace twelve single exit port pluggable units that are currently installed in an immersion chamber with twelve dual exit port pluggable units, the operator need only: 1) remove the twelve single port pluggable units that from the immersion chamber; 2) remove the transfer plate 772_1 for the twelve single port pluggable units from the immersion chamber; 3) install the transfer plate 772_2 for twelve dual exit port pluggable units into the immersion chamber; and, 4) plug the twelve dual exit port pluggable units into the newly installed transfer plate 772_2 within the immersion chamber.

Notably, as indicated just above, often times multiple pluggable units are to be simultaneously installed into the immersion chamber. As indicated by the transfer plate embodiments 772_1 and 772_2 of FIGS. 7a and 7b, a single transfer plate 772_1, 772_2 can be used to interface with the multiple pluggable units that are simultaneously installed into the immersion chamber. In a simplest case, also as observed in FIGS. 7a and 7b, all of the pluggable units have a same chassis backplane interface (i.e., each pluggable unit has the same fluid exit port arrangement and connector type) which results in the corresponding transfer plates 772_1 and 772_2 having a repeating pattern of a same fluid connector location and type.

In other embodiments, a single transfer plate that supports multiple pluggable units having different respective backplane interfaces has correspondingly different arrangements of fluid flow connectors.

An example is depicted in FIG. 7c. Here, the observed transfer plate 772_3 of FIG. 7c includes fluid four different repeating fluid connector arrangements 775, 776, 777, 778. The first repeating arrangement 775 can be used, e.g., to support simultaneous installment of three pluggable units having a single, large fluid exit port connector. The second repeating arrangement 776 can be used, e.g., to support simultaneous installment of three pluggable units having dual, large fluid exit port connectors. The third repeating arrangement 777 can be used, e.g., to support simultaneous installment of three pluggable units having a single, small fluid exit port connector. The fourth repeating arrangement 778 can be used, e.g., to support simultaneous installment of three pluggable units having a three large fluid exit port connectors.

Thus, the transfer plate 772_3 of FIG. 7c can be used to simultaneously operate the following within the immersion chamber: 1) three pluggable units each having a single, large fluid exit port connector (plugged into arrangement 775); 2) three pluggable units each having dual, large fluid exit port connectors (plugged into arrangement 776); 3) three pluggable units each having a single, small fluid exit port connector (plugged into arrangement 777); and, 4) three pluggable units having a three large fluid exit port connectors (plugged into arrangement 778).

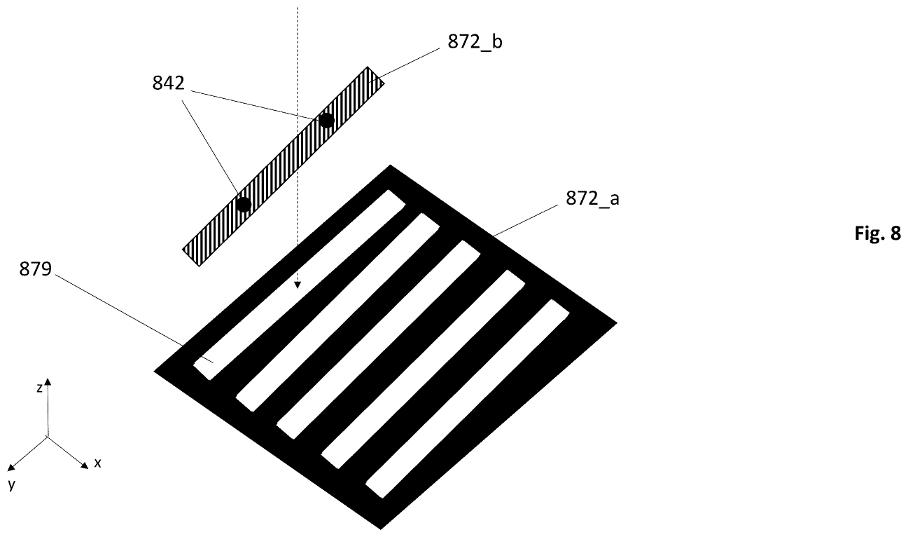

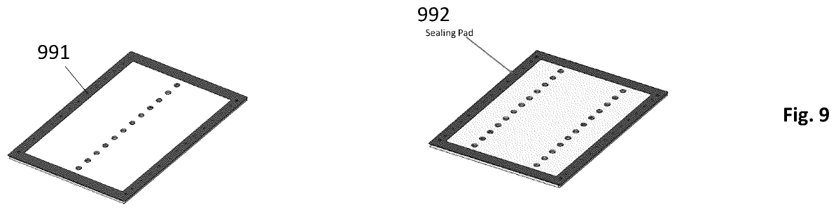

In another approach, referring to FIG. 8, the transfer plate solution is implemented as multiple plates to allow more flexibility regarding the different combinations of pluggable units having different backplane interface faces that can be simultaneously installed in a same immersion chamber.

Here, a base transfer plate 872_a is permanently or quasi permanently installed in the immersion chamber (e.g., by way of mechanical mounting fixtures as discussed above). Notably, the base transfer plate 872_a has multiple slots (for case of drawing only one 879 of the slots is labeled with a reference number). Each slot is an opening in the base transfer plate 872_a and corresponds to a location where one or more pluggable units may be installed into the immersion chamber.

An adaptor transfer plate 872_b is mounted to the base transfer plate 872_a where the adaptor transfer plate 872_b has a particular arrangement of one or more fluid connectors that are designed to align with and couple to a particular one or more electronic pluggable units having a specific backplane interface design. In the particular example of FIG. 8, the depicted adaptor transfer plate 872_b, e.g., has a pair of fluidic connectors 842 that are designed to interface with a single pluggable unit having a corresponding pair of fluid exit ports.

Notably, another adaptor transfer plate having a completely different arrangement of fluid connector(s) to align and couple with a pluggable unit having a different backplane interface than the particular interface that adaptor plate 872_b is designed to mate with can be mounted to the base transfer plate 872_b at any of the slots other than slot 879. As such, in this manner, each pluggable unit can have its own dedicated adaptor transfer plate and any arrangement of different pluggable units can be simultaneously plugged into the immersion chamber.

In various embodiments a single adaptor transfer plate can be designed to couple with more than one pluggable unit and the corresponding slot in the base transfer plate can be, e.g., wider to accommodate the more than one pluggable unit.

As discussed above, the slots corresponds to openings in the base transfer plate 872_b that permit the fluid flow that exits a pluggable unit to flow “beneath” the base transfer plate 872_b (as observed in FIG. 8) through the fluid connectors that are integrated on the adapter transfer plate that the pluggable unit is coupled to.

In any/all of the embodiments discussed above with respect to FIGS. 7a through 7c and FIG. 8, the transfer plate (or combination adapter and base transfer plates) forms a barrier between the coolant in the chamber that is being warmed by the electronics and the coolant that is exiting the chamber.

That is, referring back to FIG. 7a, the region 773 above the transfer plate 772_1 defines the region where liquid coolant cools the operating electronics, whereas, the region 774 beneath the transfer plate 772_1 defines a lower chamber from where warmer fluid exits the chamber via CDU return 743.

Fluid that is warmed by the operating electronics enters the lower region 774 from the upper region 773 by passing through the fluid exit ports of the respective electronic pluggable units and then through the fluid connectors on the transfer plate 772_1 into the lower chamber 774. Notably, cooled fluid from the CDU can, e.g., enter the upper region 773 by way of at least one input port 744 that is located on the side of the chamber 703 at the upper region 773.

In various embodiments, in order to form the barrier between the upper 773 and lower 774 regions, the transfer plate 772_1 is designed to be mounted to the chamber 703 such that the two regions 773, 774 are isolated/scaled from one another. So doing forces fluid that flows from the upper region 773 to the lower region 774 to only flow through the connectors in the transfer plate solution, which, in turn, increases the fluid flow through the flow enhancement structures of the pluggable units that are installed in the immersion chamber.

In the case of a base transfer plate 872_a having multiple slots as discussed above with respect to FIG. 8, unused slots (slots without a pluggable unit) can be covered with a solid “blocking” adapter plate that does not have any fluidic connectors or holes to help form the physical barrier between the upper 773 and lower 774 regions. Likewise, “plugs” can be inserted into any unused connector holes in transfer plates that do not have slots such as the transfer plates of FIGS. 7a-c.

FIG. 9 shows, e.g., rubber seals that can be placed around the edges of a transfer plate to form a seal between the transfer plate and whatever frame or other structure exists within the immersion chamber that the transfer plate mounts to. Seals 991, 992 are shown for both the transfer plate 772_1 of FIG. 7a and the transfer plate 772_2 of FIG. 7b.

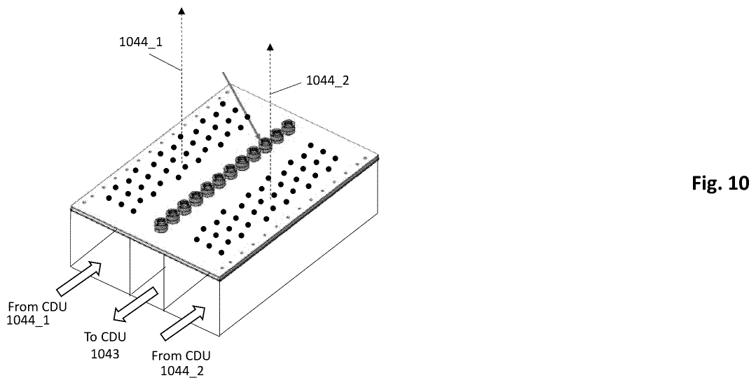

FIG. 10 depicts another embodiment in which the space beneath the transfer plate is partitioned to support both cooled liquid flows 1044_1, 1044_2 from the CDU into the immersion chamber and warmed liquid flows 1043 that are received through the transfer plate from the pluggable units' respective flow enhancement structure and directed back to the CDU. Here, as observed in FIG. 10, the space beneath the transfer plate is partitioned to form cooled fluid input channels (that receive cooled fluid 1044_1, 1044_2 from the CDU) on both sides of a central CDU return channel that returns warmed fluid 1043 back to the CDU.

The cooled fluid flows 1044_1, 1044_2 enter the region of the chamber above the transfer plate by way of holes that are formed in the transfer plate above the cooled fluid input channels that reside beneath the transfer plate. In this case the immersion chamber can operate, e.g., as described above with respect to FIG. 5a. Further embodiments can additionally bring cooled fluid from the CDU into the sides of the region above the transfer plate as depicted in FIG. 7a.

In further embodiments, e.g., in order to support additional configuration flexibility regarding the combinations of pluggable units having different backplane interface designs that can be simultaneously installed in the immersion chamber, the backplane interface of the pluggable unit is replaced with an adapter backplane interface that changes the nominal backplane interface of the pluggable unit.

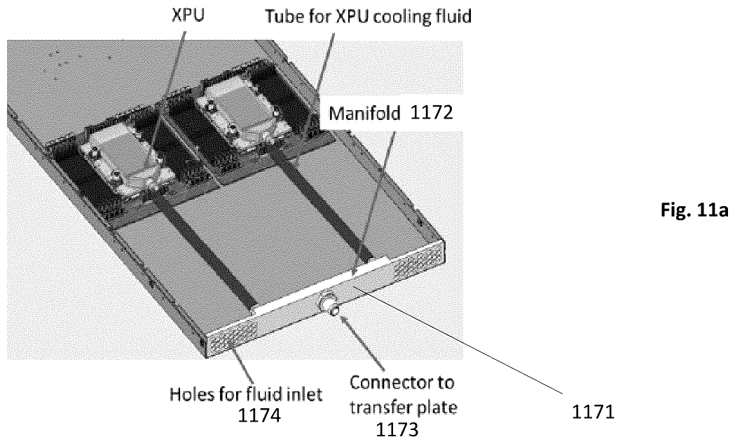

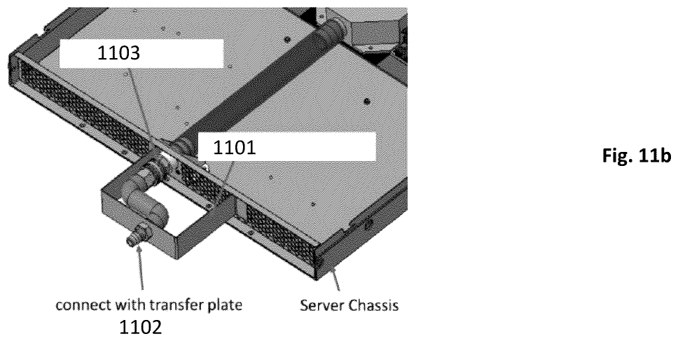

FIG. 11a depicts an example. As observed in FIG. 11a, the pluggable unit nominally has a backplane interface that includes dual exit port fluid connectors (one exit port fluid connector for each flow enhancement structure). However, the nominal backplane interface is instead replaced with an adapter backplane interface panel 1171 that, through a manifold structure 1172, changes the unit's backplane interface to a single exit port interface. Here manifold structure 1172 accepts the output fluid flow from both flow enhancement structures and forces them to flow through the single output port 1173. The manifold structure 1172 can be formed directly in the backplane interface panel 1171. Note that the particular backplane interface of FIG. 11 includes holes 1174 to also receive cooled fluid input as per the approach of FIG. 10.

FIG. 11b depicts another pluggable unit backplane interface adapter approach in which the nominal design of the pluggable unit's backplane interface is changed with an adaptor that is added as an extension to the nominal backplane interface panel rather than as an replacement for it. Here, extension 1101 is added to change the location of the pluggable unit's single exit port. Thus, extension 1101 can be added to allow the pluggable unit to plug into a transfer plate having an input connector that aligns with output connector 1102 but not nominal output connector 1103.

Note that, for any of the embodiments described above with respect to FIGS. 7a-c, 8, 9, 10 and 11a-b, the fluid flow through the transfer plate can be gravitationally induced by coupling a plenum downstream from the chamber's fluid output CDU return line as discussed above with respect to FIGS. 5a-c above. By contrast, in other embodiments, the chamber's fluid output CDU return line is coupled to a CDU pump without a plenum such that the fluid flow through the transfer plate is determined by the CDU pump speed rather than gravity.

Note that embodiments above have emphasized a transfer plate that is substantially rectangular and planar. Notably, other embodiments may include other shapes (e.g., oval, circular) and/or that are not planar (e.g., have curved surfaces). As such, the teachings of Section 2 can be extended more generally to a transfer member rather than a transfer plate, specifically.

3. Immersion Bath Chamber with Overflow Chamber

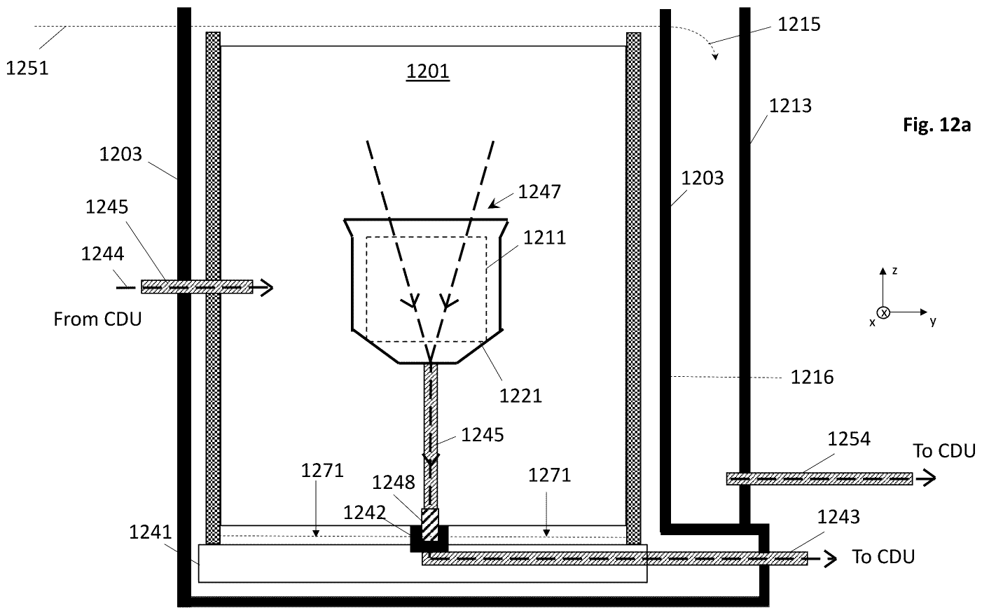

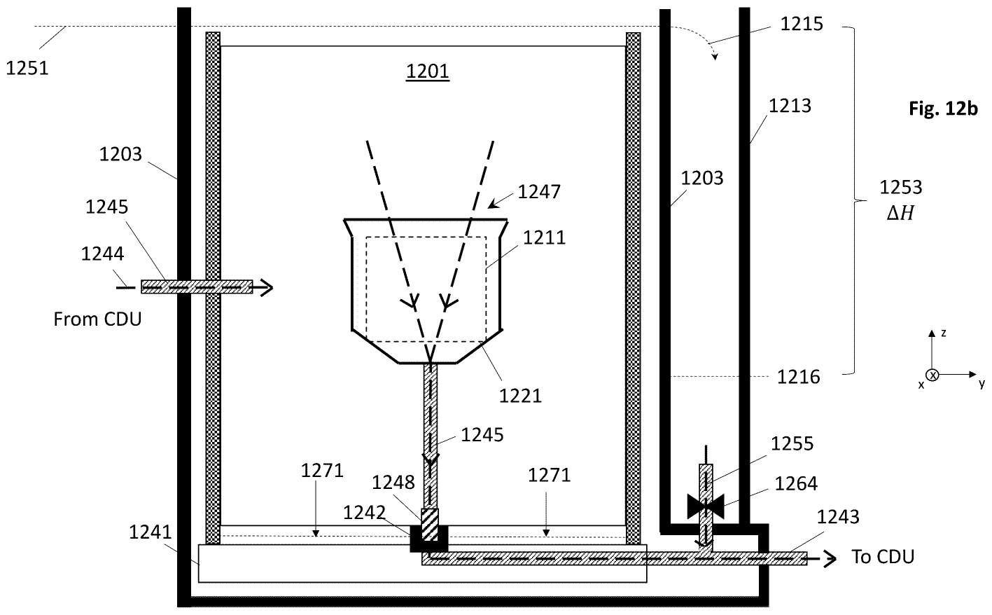

FIGS. 12a and 12b pertain to another approach in which an overflow chamber 1213 is appended to the main immersion bath chamber 1203. In both of the approaches of FIGS. 12a and 12b, “overflow” fluid within the main chamber is allowed to flow 1215 from the main chamber 1203 into the overflow chamber 1213. For example, holes can be formed in a sidewall of the main chamber 1203 that allows fluid into the main chamber to flow 1215 into the overflow chamber 1213 when the fluid within the main chamber reaches the height 1251 of the holes in the chamber sidewall.

In the approach of FIG. 12a, once fluid enters 1215 the overflow chamber 1213 it is returned to the CDU by way of its own dedicated CDU return line 1254 that is separate from the CDU return line 1243 through which fluid within the main chamber 1203 (and not the overflow chamber) exits the main chamber 1203. By contrast, in the approach of FIG. 12b, the overflow chamber's CDU return line is fluidically coupled to the main chamber's CDU return line through a valve 1264. When the valve 1264 is open, as described in more detail below, the overflow chamber 1213 is akin to a plenum which induces a gravitational flow component in the flow through the CDU return line 1243.

In the approach of FIG. 12a, both CDU return lines 1254, 1243 can be directly coupled to a CDU or a pair of CDUs. In the case of the later, separate CDUs are coupled to the different CDU return lines 1254, 1243, respectively.

Notably, in this particular approach, the fluid that exits the system from the main chamber CDU return line 1243 can be fluid that is heated by high temperature/performance chips that are cooled by fluid flow through a flow enhancement structure 1221. By contrast, the fluid that exits the system from the overflow CDU return line 1254 can be fluid that is merely warmed by lower temperature/performance chips that are cooled via convection from coolant current flows within the main chamber 1203. Thus, the main chamber CDU return line 1243 can be coupled to a higher performance CDU with a high heat removal capacity, whereas, the overflow chamber CDU return line 1254 can be coupled to lower performance (e.g., cheaper) CDU with a lower heat removal capacity.

Alternatively, one or both the CDU return lines 1254, 1243 can be coupled to a plenum to induce a gravitationally induced flow out of the particular chamber that the CDU return line is coupled to. Likewise, in the approach of FIG. 12b, the CDU return line 1243 can be coupled directly to a CDU or a plenum.

In the system of FIG. 12a, the level of the fluid in the overflow chamber 1213 is a function of the rate at which overflow fluid flows 1215 into the main chamber (which is a function of the rate at which input fluid enters 1244 the main chamber via input line 1245) and the rate at which fluid is drawn from the overflow CDU return line 1254 (e.g., as established by the pump speed of a CDU that the overflow CDU return line 1254 is coupled to).

By contrast, in the system of FIG. 12b, the level of the fluid in the overflow chamber 1213 is a function of the rate at which the overflow fluid flows 1215 into the overflow chamber 1213, the setting of the opening in valve 1264 and the rate at which fluid is drawn from the CDU return line 1243 (e.g., as established by the pump speed of a CDU that the main CDU line is coupled to).

These and other features are described in more detail further below.

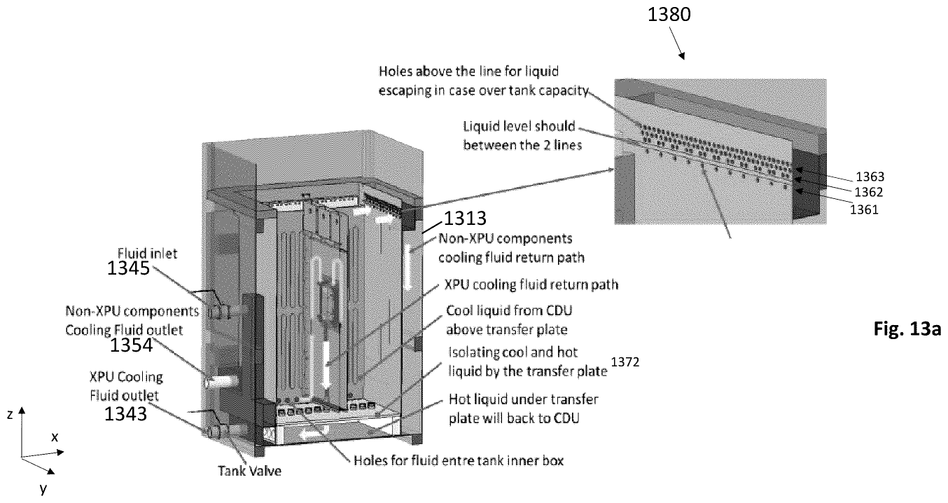

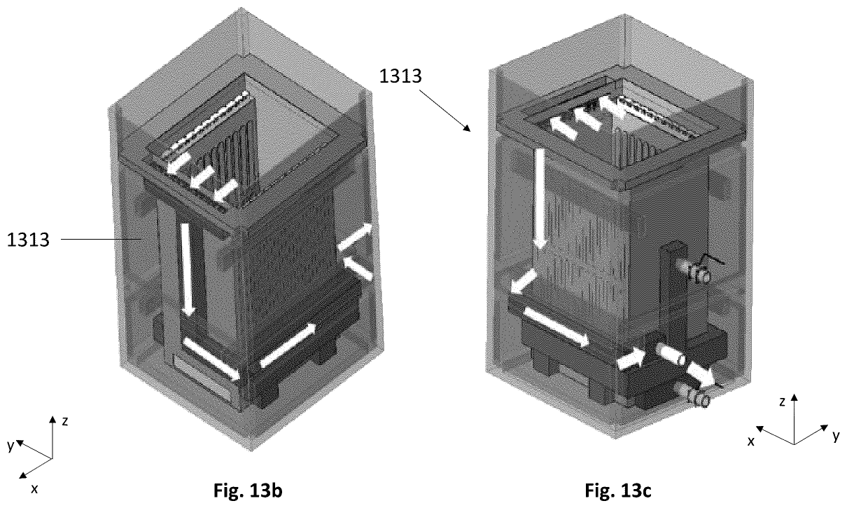

FIGS. 13a and 13b depict a more detail view of an embodiment of the approach of FIG. 12a. As observed in FIG. 13a, the main chamber includes a transfer plate 1372 as discussed above in Section 2.0. FIG. 13a also depicts the main chamber fluid input line 1345, the main chamber CDU return line output 1343 and the overflow chamber CDU return line output 1354.

Inset 1380 shows sets of holes 1361, 1362, 1363 in a sidewall of the main chamber to allow fluid to flow from the main chamber into the overflow chamber. Notably, the density of the holes increases moving up the sidewall. That is: 1) at a first lower level there is a lowest density of holes 1361; 2) at a second middle level there is a medium density of holes 1362; and, 3) at a third highest level there is a highest density of holes 1363. With this arrangement, the rate of overflow into the overflow chamber will increase as the level of coolant in the main chamber rises within the main chamber.

Specifically: 1) when the coolant level in the main chamber is below the level of the lower set of holes 1361 there is no overflow into the overflow chamber; 2) when the coolant level in the main chamber rises above the level of the lower set of holes 1361 but remains beneath the level of the second set of holes 1362 there is lesser overflow into the overflow chamber; 3) when the coolant level in the main chamber rises above the level of the second set of holes 1362 but remains beneath the level of the third set of holes 1363 there is medium overflow into the overflow chamber; and, 4) when the coolant level in the main chamber rises above the level of the third set of holes 1363 there is high overflow into the overflow chamber.

Such hole designs can affect the flow rate into the overflow chamber resulting in the level of fluid within the overflow chamber having an effect on the fluid level within the overflow chamber (along with flow rate into the main chamber and the flow rate along the overflow CDU return line).

The particular embodiment of FIG. 13a also includes the overflow chamber 1313 on one side of the main chamber and the overflow CDU return line output 1354 on the other side of the main chamber. In this particular design, an overflow return channel is formed around three sides of the main chamber before exiting the system. FIGS. 13b and 13c depict two different views of the system to more clearly show this particular CDU return channel design.

Referring now to the particular approach of FIG. 12b, as discussed above, the overflow chamber CDU return line 1255 is coupled to the CDU return line 1243 through a valve 1264. When the valve 1264 is open and there is overflow 1215 into the overflow chamber 1213, the flow through the CDU return line 1243 is a combination of the flow 1245 from the main chamber and the flow from the overflow chamber 1213. This particular arrangement allows for different operational extremes and a wide range of possible operational variations between these extremes.

At a first extreme, the valve 1264 is fully closed and the CDU return line 1243 is coupled to a CDU pump. In this case, the draw of fluid flow from the main chamber is determined by the CDU pump speed and there is no fluid flow from the overflow chamber 1213. At the other extreme, the valve 1264 is fully open and the CDU pump is turned off. In this case, the open valve 1264 causes the overflow chamber 1213 to act akin to a plenum and the draw of fluid flow 1245 from the main chamber is determined by gravitational forces as described above with respect to FIG. 5a.

These two extremes can be used to modulate the energy consumed by the CDU as a function of the workload being performed by the electronics within the immersion bath chamber.

Specifically, if the workload of the high performance semiconductor chips within the immersion bath is high, the system can be configured into the first extreme in which the valve 1264 is closed and the fluid draw 1245 from the main chamber is determined by the CDU pump speed. In this case, the rate at which fluid is drawn 1245 from the main chamber can exceed by many factors whatever rate could otherwise be achieved with gravity induced draw if the system were configured in the second extreme. Said another way, when configured in the first extreme, the CDU pump consumes (potentially high amounts of) energy to induce sufficiently high fluid flow draw 1245 from the main chamber to adequately cool the electronics when the electronics are under heavy workload.

By contrast, if the workload of the high performance semiconductor chips is minimal, the system can be configured in the second extreme in which the valve 1264 is fully opened and the CDU pump is turned off. In this case, fluid flow 1245 from the main chamber is induced by gravity and the CDU consumes little/no energy. Thus, when configured in the second extreme, the CDU pump consumes little/no energy but the gravity induced fluid flow draw from the main chamber is sufficient to cool the high performance semiconductor chips when they are operating, e.g., at light workload.

The system can also be placed in any of a wide range of operational configurations between these two extremes. For example, as the workload of the high performance semiconductor chips decreases, CDU pump speed can be lowered and/or the valve opening can be widened. Likewise, e.g., as the workload of the high performance semiconductor chips increases, CDU pump speed can be raised and/or the valve opening can be narrowed.

Here, the total fluid draw from the system through CDU return line 1243 can be caused by a combination of CDU pump draw and gravity where the CDU pump speed determines the pump draw component of the total draw and the setting of the valve 1264 opening determines the gravity induced component of the total draw.

Because of the CDU pump energy efficiencies can be gained with gravitational induced flow, a number of embodiments choose to emphasize gravity induced flow when feasible. In these embodiments, CDU pump speed is reduced and/or is greatly reduced. Nevertheless, CDU pump speed can remain non-zero to, e.g., effect a “baseline” fluid flow draw from the system.

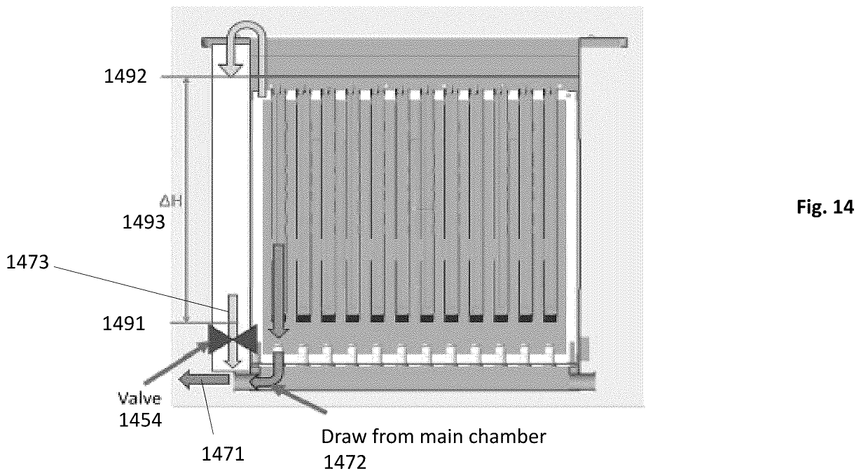

FIG. 14 depicts the system when the valve 1454 is open and the CDU pump is operating. If CDU pump speed remains constant, the level 1491 of the coolant in the overflow chamber will be a function of the valve opening. Specifically, if the valve opening is narrowed, the level 1491 of the coolant in the overflow chamber will rise, whereas, if the valve opening is widened, the level of the coolant 1491 in the overflow chamber will fall. In the case of the former, the gravity induced component of the total fluid flow draw 1471 from the system will diminish and in the case of the later, the gravity induced component of the total fluid flow draw 1471 from the system will increase.

In any/all of these situations, the fluid flow draw 1472 from the main chamber will be a function of the height difference ΔH 1493 between the fluid level 1492 in the main chamber and the fluid level 1491 in the overflow chamber.

Specifically, when ΔH 1493 is small (valve opening is narrow), there is a small fluid flow 1473 from the overflow chamber into the CDU return line which results in larger fluid flow draw 1472 from the main chamber. By contrast, when ΔH is large (valve opening is large), there is a large fluid flow 1473 from the overflow chamber into the main CDU return line which results in smaller fluid flow draw 1472 from the main chamber.

In this manner, with constant CDU pump speed, the rate of the fluid flow draw 1472 from the main chamber can be modulated/varied by modulating/varying the size of the valve opening. Specifically, if chip workload increases the valve opening can be narrowed to increase the fluid flow draw 1472 from the main chamber, whereas, if chip workload decreases the valve opening can be widened to reduce the fluid flow draw 1472 from the main chamber.

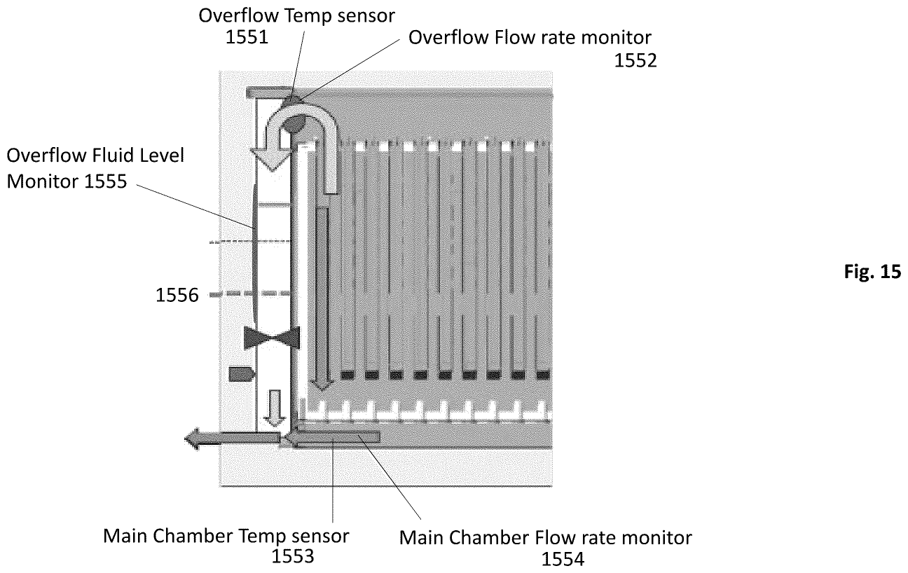

As observed in FIG. 15, in various embodiments the level of the coolant within the overflow chamber is monitored by a monitor 1555 and certain actions are (or inactions) are implemented based on the level of the coolant within the overflow chamber. As a basic case, as described above, the rate of fluid flow draw 1472 from the main chamber can be adjusted by widening/narrowing the valve to effect a specific ΔH 1493 between the overflow and main chamber fluid levels 1491, 1492. Here, the level 1491 of the coolant within the overflow chamber can be monitored by monitor 1555 to ensure that a desired ΔH 1493 is achieved.

Moreover, minimum and/or maximum fluid levels can also be established for the fluid level 1491 within the overflow chamber. Here, the minimum and/or maximum levels can be adjusted for any desired ΔH. Additionally, in various embodiments, there is a “warning line” 1556 that the fluid level within the overflow chamber is not supposed to fall beneath irrespective of the total fluid draw from the system. In various embodiments the warning line 1556 is set above the valve so that the effectiveness of the valve is ensured.

In still other embodiments, even though gravity induced flow is being utilized (the valve is open), the CDU pump can active and the CDU pump speed can be modulated to adjust, e.g., the baseline rate of fluid flow draw from the main chamber in response to, e.g., changing conditions within the chamber and/or the workload of the high performance semiconductor chips.

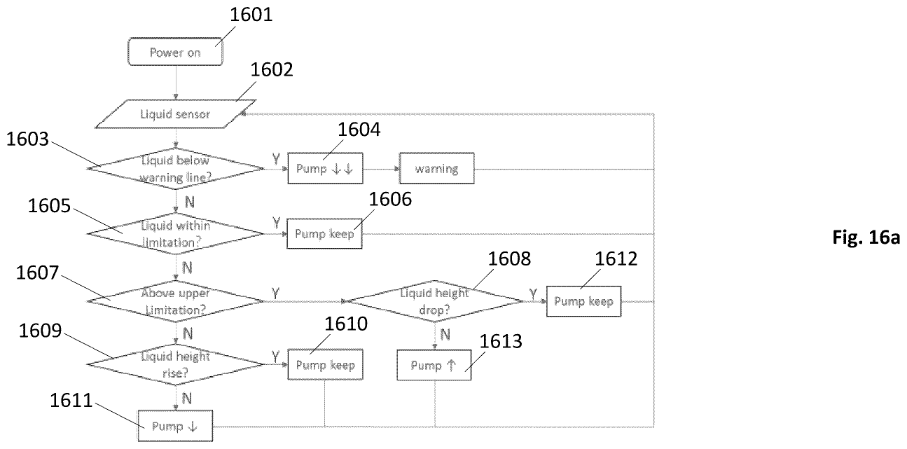

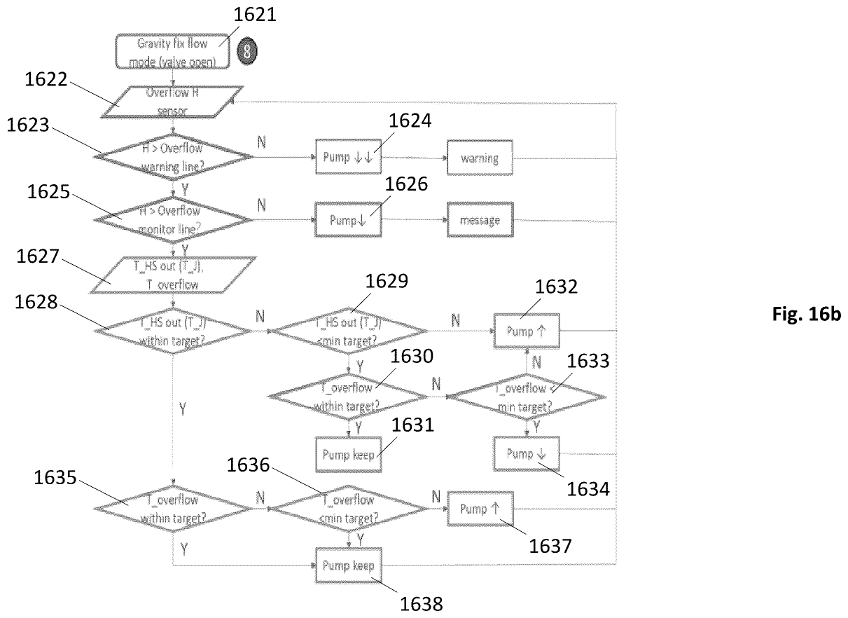

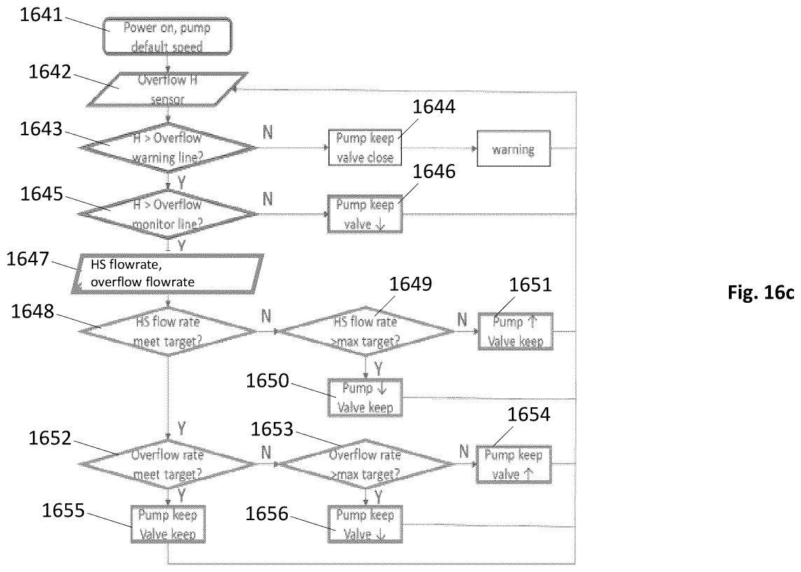

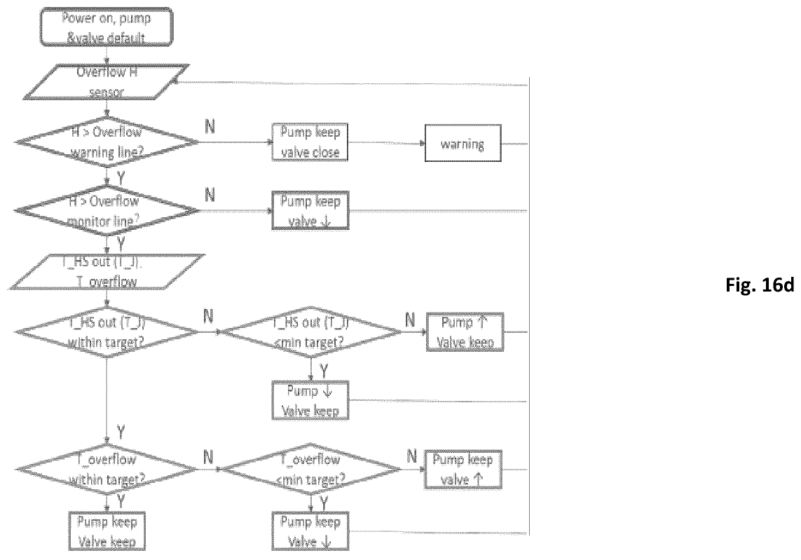

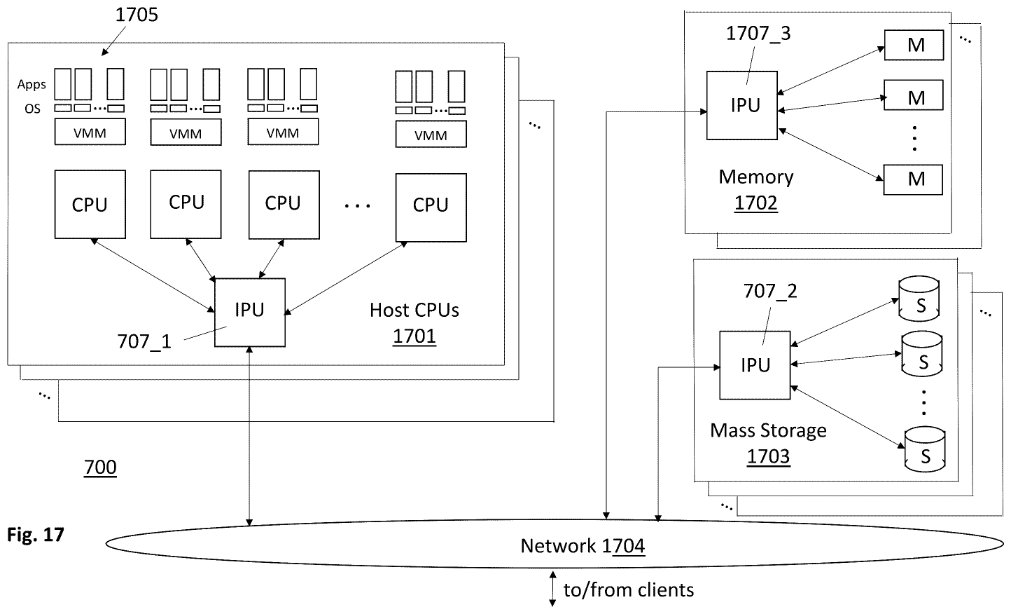

FIGS. 16a through 16d explore additional embodiments where gravity induced fluid flow from the main chamber is being relied upon to cool the electronics (the valve is open) but CDU pump speed is also variable as a function of observed conditions.

FIG. 16a shows a method for modulating the CDU pump speed to keep the fluid level within the overflow chamber above its minimum level setting and beneath its maximum level setting. Initially the power is turned on 1601 and readings are taken 1602 from the fluid level monitor 1555 within the overflow chamber.

If the fluid level in the overflow chamber falls below 1603 the “warning line” 1556 the CDU pump speed is significantly reduced 1604 to reduce the rate at which fluid is drawn from the system, which, in turn, reduces the rate at which liquid is drawn from the overflow chamber. With reduced fluid flow draw from the overflow chamber the fluid level in the overflow chamber should rise.

By contrast, if the fluid level is where it should be (above the minimum level setting and beneath the maximum level setting), the pump speed is not changed to ideally keep the existing fluid level within the overflow chamber 1603, 1605, 1606.

If the fluid level within the overflow chamber is above the maximum level but the fluid level is falling within the overflow chamber, the pump speed is kept constant 1607, 1608, 1612 (under the current conditions, the fluid level within the chamber is expected to eventually fall below the maximum level).

If the fluid level within the overflow chamber is above the maximum level but is not falling, the CDU pump speed is increased to increase total fluid draw from the system, which, in turn, increases the fluid flow rate from the overflow chamber 1607, 1608, 1613. The increased fluid flow rate from the chamber should lower the fluid level within the overflow chamber.

If the fluid level within the overflow chamber is beneath its minimum level, the control system keeps the pump speed constant if the fluid level is rising 1609, 1610. Otherwise the pump speed is tweaked downward 1609, 1611.

FIG. 16b depicts another embodiment where the overflow fluid level is maintained to be above some level (“monitor line”) that is above the “warning” level 1623, 1624, 1625, 1626. The CDU pump speed is then adjusted based on temperature readings of the overflow fluid (“T_overflow”) and the fluid being drawn from the main chamber (“T_HS out (T_J)”). Both measured temperatures are assigned specific target min/max settings (ranges). Here, temperature sensors 1551, 1553 are placed in the system to measure the respective temperature of the overflow fluid and main chamber drawn fluid.

Specifically, if both temperatures are within their assigned ranges the CDU pump speed is kept constant 1628, 1635, 1638. If the temperature of the fluid being drawn from the main chamber is within its assigned range but the temperature of the overflow fluid is above its maximum setting the CDU pump speed is increased 1628, 1635, 1636, 1637 (which increases the rate at which heat is removed from the system which should decrease the temperature of the fluid in the main chamber).

If the temperature of the fluid being drawn from the chamber is within its assigned range but the temperature of the overflow fluid is beneath its minimum setting the CDU pump speed is kept constant 1628, 1635, 1636, 1638. Here, e.g., with a flow enhancement structure in place for the high performance semiconductor chips, the temperature of the overflow liquid (which is measuring the temperature of the fluid that is cooling the chips other than the high performance chips) is less important. As such, rather than lower the CDU pump speed and risk raising the temperature of the fluid that is cooling the high performance semiconductor chips, the non-high performance chips are allowed to be cooled at a temperature that is cooler than necessary.

If the temperature of the fluid being drawn from the main chamber is above its maximum setting the pump speed is increased to increase the overall heat removal capacity of the system 1628, 1629, 1632.

If the temperature of the fluid being drawn from the main chamber is beneath its minimum setting and the temperature of the overflow fluid is within its assigned range, the CDU pump speed remains constant 1628, 1629, 1630, 1631 (with the high performance chips being more than adequately cooled, the system maintains the overflow temperature within its assigned min/max levels).

By contrast, if the temperature of the fluid being drawn from the main chamber is beneath its minimum setting and the temperature of the overflow fluid is not within its assigned range 1628, 1629, 1630, 1633, the setting the pump speed is adjusted 1632, 1634 in attempt to bring the overflow fluid within its assigned range (with the high performance chips being more than adequately cooled, the system attempts to bring the overflow temperature within its assigned min/max levels).

FIG. 16c depicts another embodiment where, again, the overflow fluid level is maintained to be above some level (“monitor line”) that is above the “warning” level 1642, 1643, 1644, 1645, 1646. Notably, however, the valve opening (rather than CDU pump speed) is adjusted in order keep the overflow fluid level above the “monitor line” level 1644, 1646 (wider valve opening lowers the overflow fluid level whereas narrower valve opening raises the overflow fluid level).

The CDU pump speed is then adjusted based on readings of the rate of the overflow fluid's flow (“overflow_flowrate”) and the rate of the fluid flow draw from the main chamber (“HS_flowrate”). Both monitored flows are assigned respective flow rate target min/max settings (ranges). Here, flow rate monitors 1552, 1554 are placed in the system to measure the two flow rates.

As observed in FIG. 16c, the CDU pump speed and the valve opening are kept constant if both flow rates are within their respective target ranges 1648, 1652, 1655.

If the flow rate from the main chamber is within its target range but the overflow rate is above its maximum target, the valve opening is narrowed 1648, 1652, 1653, 1656. By contrast, if the flow rate from the main chamber is within target but the overflow rate is beneath its minimum target, the valve opening is widened 1648, 1652, 1653, 1654. The CDU pump speed is kept constant with either of these scenarios. Here, with the flow rate that is drawn from the main chamber (which is the flow that cools the higher performance chips) being within target, CDU pump is not tampered with to avoid not adequately cooling the high performance chips.

By contrast, if the flow rate being drawn from the main chamber is beneath its minimum target setting the CDU pump speed is increased 1648, 1649, 1651 whereas if the flow rate being drawn from the main chamber is above its maximum target setting the CDU pump speed is decreased 1648, 1649, 1650. In both scenarios the valve opening is kept constant. Here, again, emphasis is placed on ensuring the high performance chips are adequately cooled. Specifically, main chamber fluid flow draw (which determines heat removal capacity from the high performance chips) is controlled with adjustments made in CDU pump speed directly from the main chamber flow readings.

FIG. 16d shows a similar approach to the approach of FIG. 16c but where the adjustments are made in response to temperature readings of the overflow and main chamber draw fluids rather than their rate of flows.

In any of the above described embodiments of Section 3 a control system can be communicatively coupled to any/all of the sensors and monitors 1551, 1552, 1553, 1554, 1555, the setting mechanism for the valve (e.g., an electro-mechanical servo motor) and/or the setting mechanism for the pump speed (e.g., an input voltage and/or current that is applied to the pump motor). The control system can include logic circuitry and/or a processor that executes software to implement any of the control operations described just above including adjusting a valve setting or a pump speed in view of operational workload of electronics within the main chamber, and/or, an observed temperature of the main chamber's fluid and/or the overflow chamber's fluid, and/or, an observed flow rate of the main chamber's fluid and/or the overflow chamber's fluid.

Note also that the sidewall holes of inset 1380 of FIG. 13a can be included in embodiments that adopt the approach of FIG. 12b (capable of inducing gravitational flow).

Note that the immersion bath chamber improvements described above in Sections 1 and 3 can (but need not) include a transfer plate as described above in Section 2. Moreover, the immersion bath chamber improvements described above in Section 3 can include a sealed/pressurized main chamber as described above in Section 1. An immersion bath chamber having any of the improvements as described above in Sections 1, 2 and 3 can receive one or more pluggable units having at least one flow enhancement structure as described above, e.g., in reference to FIGS. 5a-d. Contra-wise, an immersion bath chamber having any of the improvements as described above in Sections 1, 2 and 3 need not be configured to receive a pluggable unit having at least one flow enhancement structure as described above, e.g., in reference to FIGS. 5a-d.

FIG. 17 shows a new, emerging computing environment (e.g., data center) paradigm in which “infrastructure” tasks are offloaded from traditional general purpose “host” CPUs (where application software programs are executed) to an infrastructure processing unit (IPU), data processing unit (DPU) or smart networking interface card (SmartNIC), any/all of which are hereafter referred to as an IPU.

Networked based computer services, such as those provided by cloud services and/or large enterprise data centers, commonly execute application software programs for remote clients. Here, the application software programs typically execute a specific (e.g., “business”) end-function (e.g., customer servicing, purchasing, supply-chain management, email, etc.).

Remote clients invoke/use these applications through temporary network sessions/connections that are established by the data center between the clients and the applications. A recent trend is to strip down the functionality of at least some of the applications into more finer grained, atomic functions (“micro-services”) that are called by client programs as needed. Micro-services typically strive to charge the client/customers based on their actual usage (function call invocations) of the micro-service application.

In order to support the network sessions and/or the applications' functionality, however, certain underlying computationally intensive and/or trafficking intensive functions (“infrastructure” functions) are performed.

Examples of infrastructure functions include encryption/decryption for secure network connections, compression/decompression for smaller footprint data storage and/or network communications, virtual networking between clients and applications and/or between applications, packet processing, ingress/egress queuing of the networking traffic between clients and applications and/or between applications, ingress/egress queueing of the command/response traffic between the applications and mass storage devices, error checking (including checksum calculations to ensure data integrity), distributed computing remote memory access functions, etc.

Traditionally, these infrastructure functions have been performed by the CPU units “beneath” their end-function applications. However, the intensity of the infrastructure functions has begun to affect the ability of the CPUs to perform their end-function applications in a timely manner relative to the expectations of the clients, and/or, perform their end-functions in a power efficient manner relative to the expectations of data center operators. Moreover, the CPUs, which are typically complex instruction set (CISC) processors, are better utilized executing the processes of a wide variety of different application software programs than the more mundane and/or more focused infrastructure processes.

As such, as observed in FIG. 17, the infrastructure functions are being migrated to an infrastructure processing unit (IPU). FIG. 17 depicts an exemplary data center environment 1700 that integrates one or more IPUs 1707_1 to offload infrastructure functions from the host CPUs as described above.

As observed in FIG. 17, the exemplary data center environment 1700 includes pools 1701 of CPU units (e.g., multicore processors) that execute the end-function application software programs 1705 that are typically invoked by remotely calling clients. The data center 1700 also includes separate memory pools 1702 and mass storage pools 1703 to assist the executing applications. The CPU, memory storage and mass storage pools 1701, 1702, 1703 are respectively coupled by one or more networks 1704.

Notably, each pool 1701, 1702, 1703 has an IPU 1707_1, 1707_2, 1707_3 on its front end or network side. Here, each IPU 1707 performs pre-configured infrastructure functions on the inbound (request) packets it receives from the network 1704 before delivering the requests to its respective pool's end function (e.g., executing software in the case of the CPU pool 1701, memory in the case of memory pool 1702 and storage in the case of mass storage pool 1703). As the end functions send certain communications into the network 1704, the IPU 1707 performs pre-configured infrastructure functions on the outbound communications before transmitting them into the network 1704.

Depending on implementation, one or more CPU pools 1701, memory pools 1702, mass storage pools 1703 and network 1704 can exist within a single chassis, e.g., as a traditional computing system (e.g., server computer). In a disaggregated computing system implementation, one or more CPU pools 301, memory pools 1702, and mass storage pools 1703 are, e.g., separate pluggable electronic units (e.g., pluggable CPU units, pluggable memory units (M), pluggable mass storage units (S)). Although not depicted in FIG. 17, an additional accelerator pool could also be coupled to the network 1704 through its own IPU similar to the other pools. The accelerator pool can include, e.g., accelerator pluggable units that include any combination of graphics processing units (GPUs), artificial intelligence inference semiconductor chips, artificial intelligence semiconductor chips, image processing accelerators, or other types of accelerators.

Notably, a traditional computing system and/or any of the above mentioned pluggable units can be mechanically configured to be immersed in an immersion bath within an immersion chamber that includes any of the teachings described above Sections 1, 2 and 3.

In various embodiments, the software platform on which the applications 1705 are executed include a virtual machine monitor (VMM), or hypervisor, that instantiates multiple virtual machines (VMs). Operating system (OS) instances respectively execute on the VMs and the applications execute on the OS instances. Alternatively or combined, container engines (e.g., Kubernetes container engines) respectively execute on the OS instances. The container engines provide virtualized OS instances and containers respectively execute on the virtualized OS instances. The containers provide isolated execution environment for a suite of applications which can include, applications for micro-services.

Embodiments of the invention may include various processes as set forth above. The processes may be embodied in program code (e.g., machine-executable instructions). The program code, when processed, causes a general-purpose or special-purpose processor to perform the program code's processes. Alternatively, these processes may be performed by specific/custom hardware components that contain hard wired interconnected logic circuitry (e.g., application specific integrated circuit (ASIC) logic circuitry) or programmable logic circuitry (e.g., field programmable gate array (FPGA) logic circuitry, programmable logic device (PLD) logic circuitry) for performing the processes, or by any combination of program code and logic circuitry.

Elements of the present invention may also be provided as a machine-readable medium for storing the program code. The machine-readable medium can include, but is not limited to, floppy diskettes, optical disks, CD-ROMs, and magneto-optical disks, FLASH memory, ROMs, RAMS, EPROMs, EEPROMs, magnetic or optical cards or other type of media/machine-readable medium suitable for storing electronic instructions.

In the foregoing specification, the invention has been described with reference to specific exemplary embodiments thereof. It will, however, be evident that various modifications and changes may be made thereto without departing from the broader spirit and scope of the invention as set forth in the appended claims. The specification and drawings are, accordingly, to be regarded in an illustrative rather than a restrictive sense.

1. An apparatus, comprising:
an immersion bath chamber, the immersion bath chamber comprising a cover that is to seal the immersion bath chamber, the immersion bath chamber to contain coolant fluid, wherein, when the immersion bath chamber is sealed with the cover, the coolant fluid within the immersion bath chamber is to be pressurized to enhance a pressure head of a flow of a portion of the coolant fluid that is to receive heat from an electronic component within the immersion bath chamber.

2. The apparatus of claim 1 wherein the portion of the coolant fluid is to flow through a flow enhancement structure within the immersion bath chamber.

3. The apparatus of claim 1 wherein the cover includes a valve to inject a gas into the immersion bath chamber to cause the pressure head enhancement.

4. The apparatus of claim 1 wherein the immersion bath chamber includes an input to receive an input flow of the coolant fluid, wherein the input flow of the coolant fluid is to cause the pressure head enhancement.

5. The apparatus of claim 4 further comprising a valve to control the input flow of the coolant fluid into the immersion bath chamber.

6. The apparatus of claim 1 further comprising a plenum, the plenum to receive warmed fluid from the immersion bath chamber.

7. The apparatus of claim 1 wherein the apparatus is within a data center.

8. An apparatus, comprising:
an immersion bath chamber; and,
an installable/removable transfer member, the installable/removable transfer member having fluidic connectors arranged to couple to respective warmed fluid flow output ports of pluggable units to be cooled in the immersion bath chamber and that have respective backplane interface designs comprising specific arrangements of the warmed fluid flow output ports, the installable/removable member including holes through which warmed fluid that is emitted from the warmed fluid output ports is to flow.

9. The apparatus of claim 8 wherein the respective backplane interface designs are the same.

10. The apparatus of claim 8 wherein the respective backplane interface designs are different.

11. The apparatus of claim 9 wherein the respective backplane interface designs comprise respective ones of the warmed fluid flow output ports having different fluidic connector types.

12. The apparatus of claim 8 wherein the installable/removable transfer member, when installed in the immersion bath chamber, is to partition space within immersion bath chamber into a first space having an input to receive cooled coolant fluid and a second space having an output to emit warmed coolant fluid.

13. The apparatus of claim 8 wherein the installable/removable transfer member comprises additional holes through which cooled input fluid provided to the immersion bath chamber flows.

14. The apparatus of claim 8 wherein the apparatus is within a data center.

15. An apparatus, comprising:
an immersion bath chamber and an overflow chamber, the immersion bath chamber to receive one or more electronic pluggable units, the overflow chamber to receive an overflow of liquid coolant from the immersion bath chamber, wherein a first exit flow channel from the overflow chamber is coupled to a second exit fluid flow channel from the immersion bath chamber through a valve, wherein, an opening of the valve is controllable to vary a gravitational fluid flow within the immersion bath chamber.

16. The apparatus of claim 15 further comprising a control system to vary the gravitational fluid flow in response to at least one element of the set a), b), c), d) and e) where elements a), b), c), d) and e) are defined as follows:
a) a workload of electronics of the one or more electronic pluggable units;
b) a first temperature of the immersion bath chamber's liquid coolant;
c) a second temperature of the overflow chamber's liquid coolant;
d) a first flow rate of the immersion bath chamber's liquid coolant;
e) a second flow rate of the overflow chamber's liquid coolant.

17. The apparatus of claim 16 wherein the control system is to increase the opening of the valve to decrease the gravitational fluid flow.

18. The apparatus of claim 16 wherein, to increase fluid flow through the immersion bath chamber, the control system is to increase a pump speed of a pump that determines a flow rate of liquid coolant flow from the immersion bath chamber.

19. The apparatus of claim 16 wherein, the control system is to narrow and/or close the opening in the valve to increase the gravitational fluid flow.

20. The apparatus of claim 16 wherein the one or more pluggable units are capable of including a respective flow enhancement structure that is to be fluidically coupled to the second exit fluid flow channel.
